(19) United States
(12) Patent Application Publication
(10) Pub. No.: US 2024/0355899 A1
(43) Pub. Date: Oct. 24, 2024

(54) GATE STRUCTURE WITH OXYGEN BARRIER AND METHODS FOR MANUFACTURING THE SAME

(71) Applicant: TAIWAN SEMICONDUCTOR MANUFACTURING COMPANY, LTD., Hsinchu (TW)

(72) Inventors: Shen-Yang LEE, Hsinchu (TW); Chun-Da LIAO, Hsinchu (TW)

(21) Appl. No.: 18/234,567

(22) Filed: Aug. 16, 2023

Related U.S. Application Data
(60) Provisional application No. 63/461,118, filed on Apr. 21, 2023.

(51) Int. Cl. H01L 29/51; H01L 29/06; H01L 29/40; H01L 29/423; H01L 29/66; H01L 29/775

(52) U.S. Cl. CPC H01L 29/516; H01L 29/0673; H01L 29/401; H01L 29/42392; H01L 29/66439; H01L 29/775

(57) ABSTRACT

Embodiments provide a semiconductor device structure. The structure includes a semiconductor channel layer over a substrate, a gate dielectric layer disposed over the semiconductor channel layer. The gate dielectric layer includes a first high-K (HK) dielectric layer having a first dopant concentration of dipole elements, and a second HK dielectric layer having a second dopant concentration of dipole elements different than the first dopant concentration. The structure also includes a gate electrode layer deposited over the gate dielectric layer, and an insertion layer disposed between the gate dielectric layer and the gate electrode layer, wherein the insertion layer is formed of a noble metal.

### CROSS-REFERENCE TO RELATED APPLICATIONS

This application claims priority to U.S. Provisional Application Ser. No. 63/461,118 filed Apr. 21, 2023, which is incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure in accordance with some embodiments.

FIGS. 6A, 6B, and 6C are cross-sectional side views of the semiconductor device structure taken along line A-A, line B-B, and line C-C of FIG. 5, respectively.

FIGS. 7A-12A and 17A are cross-sectional side views of various stages of manufacturing the semiconductor device structure taken along cross-section A-A of FIG. 5, in accordance with some embodiments.

FIGS. 7B-12B and 17B are cross-sectional side views of various stages of manufacturing the semiconductor device structure taken along cross-section B-B of FIG. 5, in accordance with some embodiments.

FIGS. 7C-12C and 17C are cross-sectional side views of various stages of manufacturing the semiconductor device structure taken along cross-section C-C of FIG. 5, in accordance with some embodiments.

FIGS. 13-16 are enlarged views of a region of FIG. 12B showing various stages of manufacturing replacement gate structure for the semiconductor device structure, in accordance with some embodiments.

FIGS. 18A-30A, 18B-30B, 18C-30C, 18D-30D, 18E-30E, 18F-30F illustrate formation of gate structures 200A-200F for a semiconductor device, in accordance with various embodiments.

FIG. 31 illustrates a flowchart of a process for forming the gate structures 200A-200F of FIGS. 18A-30F, in accordance with various embodiments.

FIG. 32 is a cross-sectional view of a semiconductor device structure showing an intermediate stage of fabrication, in accordance with some embodiments.

FIG. 33 illustrates a cross-sectional view of a portion of the semiconductor device structure taken along cross-section E-E of FIG. 32, in accordance with some embodiments.

FIG. 34 illustrates a cross-sectional view of a portion of the semiconductor device structure taken along cross-section F-F of FIG. 32, in accordance with some embodiments.

FIGS. 35A-45A, 35B-45B, 35C-45C, 35D-45D, 35E-45E, 35F-45F illustrate formation of gate structures 300A-300F for a semiconductor device, in accordance with various embodiments.

FIG. 46 is a cross-sectional view of a semiconductor device structure showing an intermediate stage of fabrication, in accordance with some embodiments.

FIG. 47 illustrates a cross-sectional view of a portion of the semiconductor device structure taken along cross-section G-G of FIG. 46, in accordance with some embodiments.

FIG. 48 illustrates a cross-sectional view of a portion of the semiconductor device structure taken along cross-section H-H of FIG. 46, in accordance with some embodiments.

FIG. 49 illustrates a flowchart of a process for forming the gate structures 300A-300F of FIGS. 35A-45F, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as planar FETs, three-dimensional fin-line FETs (FinFETs), gate-all-around (GAA) devices (e.g., Horizontal Gate All Around (HGAA) FETs, Vertical Gate All Around (VGAA) FETs), vertical FETs, forksheet FETs, or complementary FETs (CFETs). While the embodiments of this disclosure are discussed with respect to GAA devices, implementations of some aspects of the present disclosure may be used in other processes and/or in other devices. A person having ordinary skill in the art will readily understand other modifications that may be made are contemplated within the scope of this disclosure.

With the trend of scaling, the devices size and the device footprint (i.e., a physical space required by a device) are getting smaller and smaller. In advanced technology nodes, packaging and bonding processes involving thermal process are typically performed with additional thermal budget, which would cause migration of oxygen from gate dielectric into metal gates and/or interfacial layer (IL). Additional thermal budget can cause oxidation of the metal elements in metal gates so as to become a relatively stable state. In addition, oxygen may migrate into metal gates from a first side of the gate dielectric, located between the gate dielectric and the metal gate. On the other hand, oxygen may also migrate into the IL, causing thickening of IL (due to IL re-growth) from a second side of the gate dielectric, located between gate dielectric and IL. Migration of oxygen from the gate dielectric may result in generation of oxygen vacancies in the gate dielectric, resulting in shift or controllability of flat-band voltage (VFB) of the device. As a result, the reliability of the device is compromised. For the high-K metal gate (HKMG) scheme (i.e., a structure including a gate dielectric and a metal gate, where the gate dielectric has a high dielectric constant to achieve a high I_{DS}) which is used in 28-nm technology node and below, reduction of oxygen vacancies in gate dielectrics is under continuous development to achieve a better reliability performance.

Gate stack structures disclosed herein use an ultra-thin insertion layer (i.e., oxygen barrier) on gate dielectric to block oxygen migration from gate dielectric to metal gate. The ultra-thin insertion layer can keep oxygen in insulators (i.e., gate dielectrics and interfacial layers) to reduce generation of oxygen vacancies in the gate dielectrics, and protect the metal gate from further oxidation (and thus increase the resistivity thereof), thereby resulting in less degradation of the device and improving overall reliability of the device. The ultra-thin insertion layer may be combined with a N-dipole or P-dipole process to achieve a single P-edge or N-edge work-function metal knob, thereby reducing process difficulty and cost of advanced technology nodes. Since generation of oxygen vacancies can be suppressed by the ultra-thin insertion layer, the number of thermal treatments for repairing oxygen vacancies can be reduced, thereby avoiding IL re-growth and diffusion of dopants in source/drain. The proposed gate stack structures also improve gate fill window, and achieve lower gate resistance, for multiple threshold voltage (Vth) tuning with photolithographic patterning. Multiple Vth tuning can be achieved by selectively driving N-dipole or P-dipole elements to a high-K dielectric layer of various gate structures at different device regions with various doping densities effective to tune threshold voltages for the gate structures. These techniques improve the flexibility in tuning the threshold voltage compared to conventional devices, as will be discussed below in more detail.

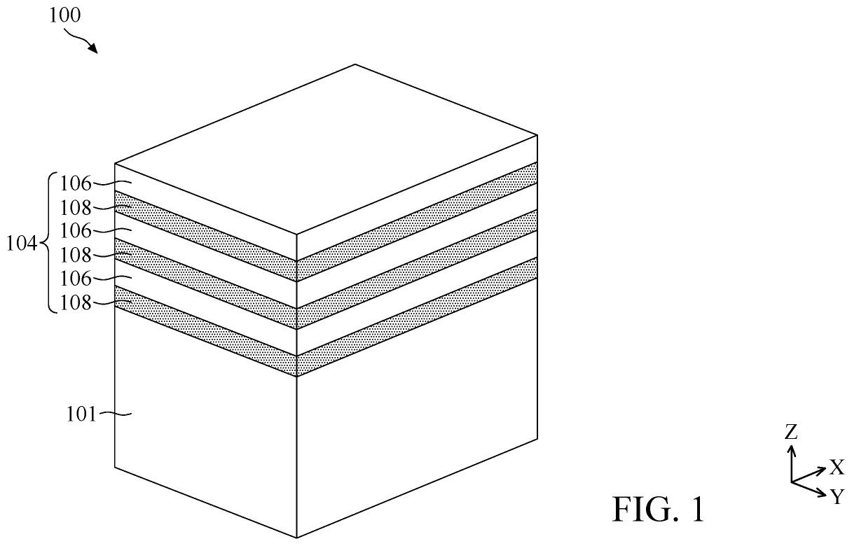

FIGS. 1-49 show exemplary processes for manufacturing a semiconductor device structure 100 according to embodiments of the present disclosure. It is understood that additional operations can be provided before, during, and after processes shown by FIGS. 1-49, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100 (e.g., nano-FET), in accordance with some embodiments. As shown in FIG. 1, a semiconductor device structure 100 includes a stack of semiconductor layers 104 formed over a front side of a substrate 101. The substrate 101 may be a semiconductor substrate, such as a bulk semiconductor, or the like. The substrate 101 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer. Other substrates, such as single-layer, multi-layered, or gradient substrates may also be used.

The substrate 101 may include various regions that have been doped with impurities (e.g., dopants having P-type or N-type conductivity). Depending on circuit design, the dopants may be, for example boron for a P-type field effect transistors (PFET) and phosphorus for an N-type field effect transistors (NFET).

The stack of semiconductor layers 104 includes alternating semiconductor layers made of different materials to facilitate formation of nanosheet channels in a multi-gate device, such as nanosheet channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of a first semiconductor material suitable for N-type nano-FETs, such as silicon, silicon carbide, or the like, and the second semiconductor layers 108 may be made of a second semiconductor material suitable for P-type nano-FETs, such as silicon germanium or the like. In some examples, the first semiconductor layers 106 may be made of Si and the second semiconductor layers 108 may be made of SiGe. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof. Each of the layers of the stack of semiconductor layers 104 may be epitaxially grown using a process such as chemical vapor deposition (CVD), atomic layer deposition (ALD), vapor phase epitaxy (VPE), molecular beam epitaxy (MBE), a metalorganic chemical vapor deposition (MOCVD) process, or other suitable growth processes.

Due to high etch selectivity between the first semiconductor materials and the second semiconductor materials, the second semiconductor material of the second semiconductor layers 108 may be removed without significantly removing the first semiconductor material of the first semiconductor layers 106, thereby allowing the first semiconductor layers 106 to be patterned to form nanosheet or nanostructure channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. Although the stack of semiconductor layers 104 is illustrated as including a second semiconductor layer 108 as the bottommost layer, in some embodiments, the bottommost layer of the stack of semiconductor layers 104 may be a first semiconductor layer 106.

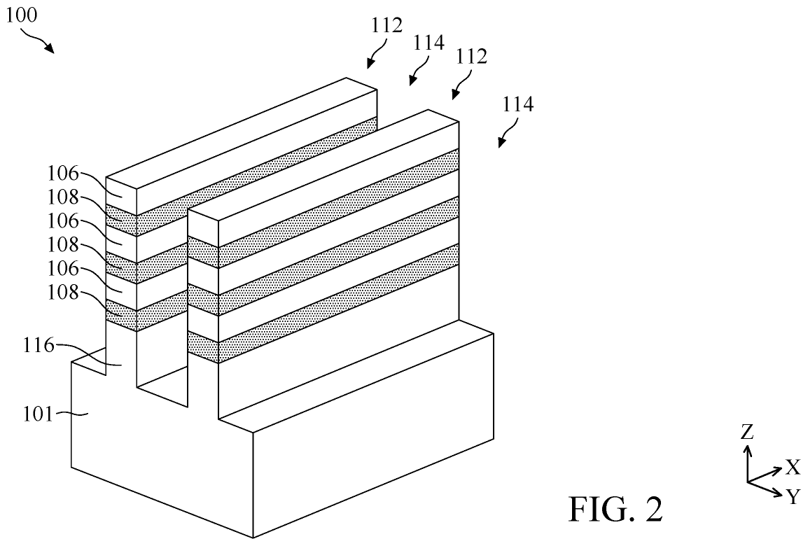

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using one or more photolithography processes and etching processes. The etching process can include dry etching, wet etching, reactive ion etching (RIE), and/or other suitable processes. The photolithography process may include double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the the fin structures 112. In any case, the one or more etching processes form trenches 114 in unprotected regions through the hard mask layer, through the stack of semiconductor layers 104, and into the substrate 101, thereby leaving the plurality of extending fin structures 112. The trenches 114 extend along the X direction.

FIG. 2 further illustrates the fin structures 112 having substantially vertical sidewalls, such that width of the fin structures 112 are substantially similar and each of the first and second semiconductor layers 106, 108 in the fin structures 112 is rectangular in shape. In some embodiments, the fin structures 112 may have tapered sidewalls, such that a width of each of the fin structures 112 continuously increases in a direction towards the substrate 101. In such cases, each of the first and second semiconductor layers 106, 108 in the fin structures 112 may have a different width and be trapezoidal in shape.

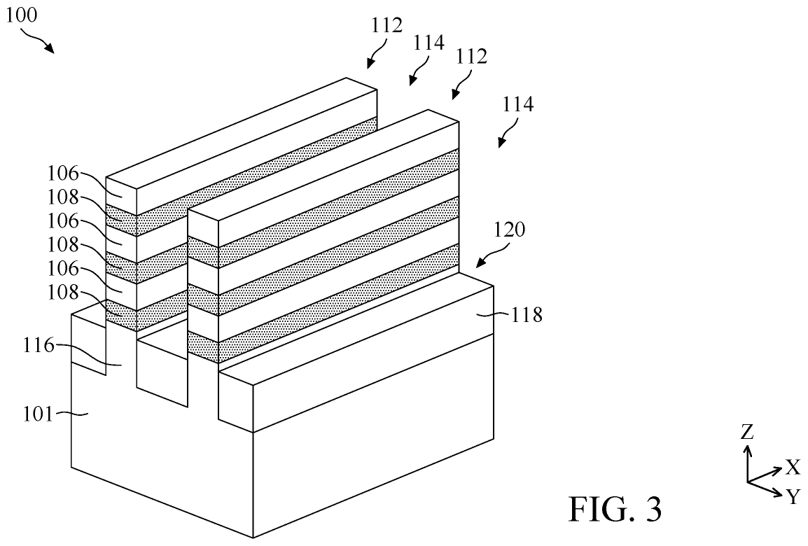

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

Thereafter, the insulating material 118 is recessed to form an isolation region 120. After recessing, portions of the fin structures 112, such as the stack of semiconductor layers 104, may protrude from between neighboring isolation regions 120. The isolation regions 120 may have top surfaces that are flat as illustrated, convex, concave, or a combination thereof. The recess of the insulating material 118 reveals the trenches 114 between the neighboring fin structures 112. The isolation region 120 may be formed using a suitable process, such as a dry etching process, a wet etching process, or a combination thereof. In one embodiment, the isolation regions 120 are formed using dilute hydrofluoric acid (dHF), which is selective to the insulating material 118 over the stack of semiconductor layers 104. Upon completion of recessing, a top surface of the insulating material 118 may be level with or below a surface of the second semiconductor layers 108 in contact with the well portion 116 formed from the substrate 101.

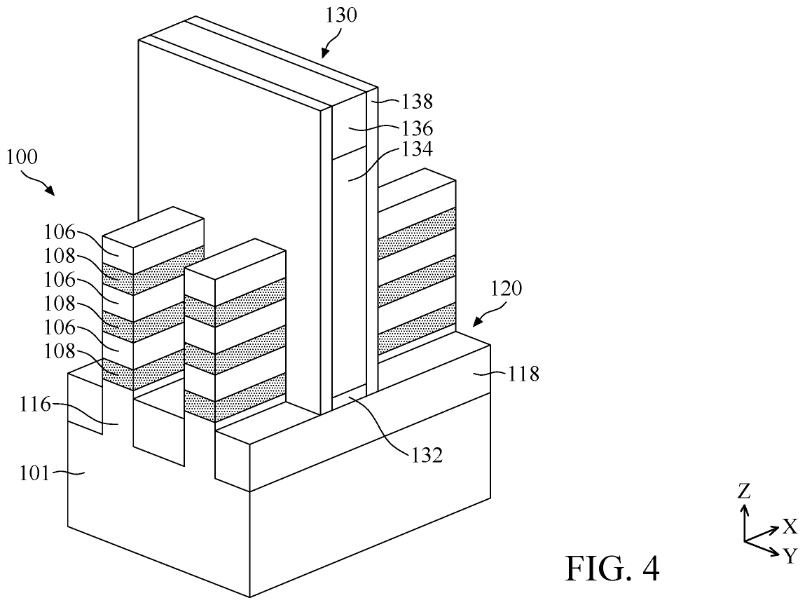

In FIG. 4, one or more sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed over sidewalls of the sacrificial gate structures 130. The gate spacers 138 may be formed by conformally depositing one or more layers for the gate spacers 138 and anisotropically etching the one or more layers, for example. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various one of the S/D regions may be connected together and implemented as multiple functional transistors. It should be understood that the source region and the drain region can be interchangeably used since the epitaxial features to be formed in these regions are substantially the same.

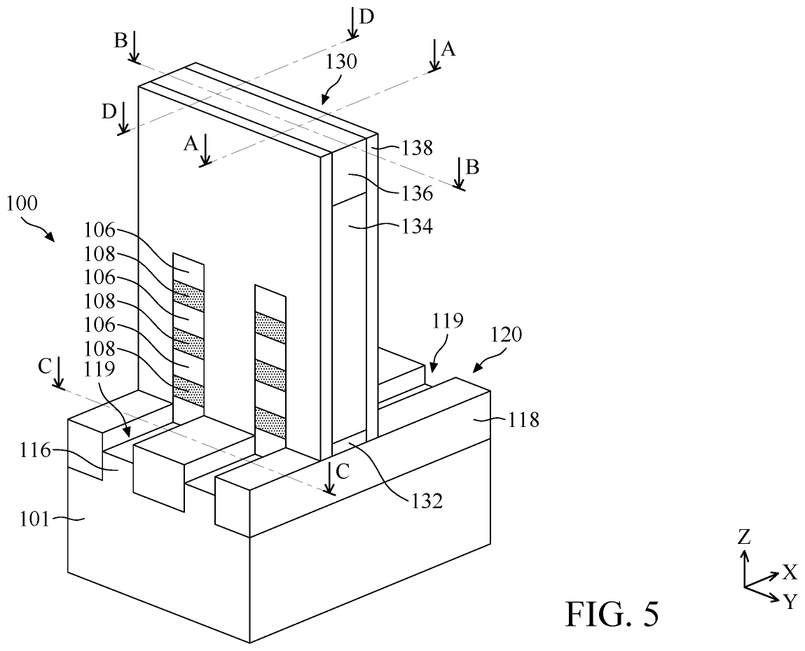

In FIG. 5, the portions of the fin structures 112 in the S/D regions (e.g., regions on opposite sides of the sacrificial gate structure 130) are recessed down below the top surface of the isolation region 120 (or the insulating material 118), by removing portions of the fin structures 112 not covered by the sacrificial gate structure 130. The recess of the portions of the fin structures 112 can be done by an etch process, either isotropic or anisotropic etch process, or further, may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. Trenches 119 are formed in the S/D regions as the result of the recess of the portions of the fin structures 112.

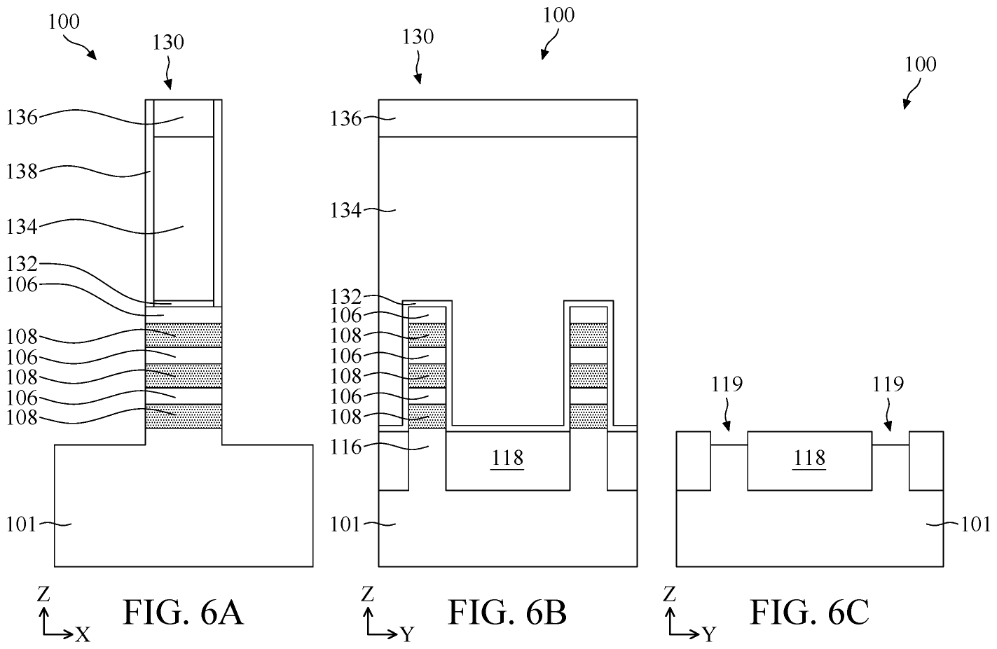

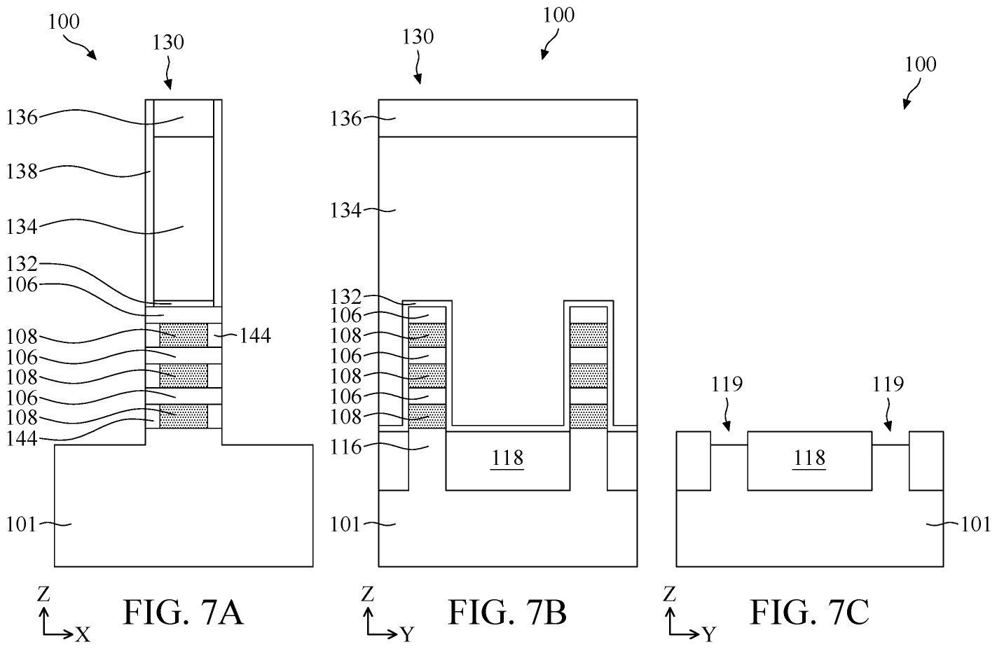

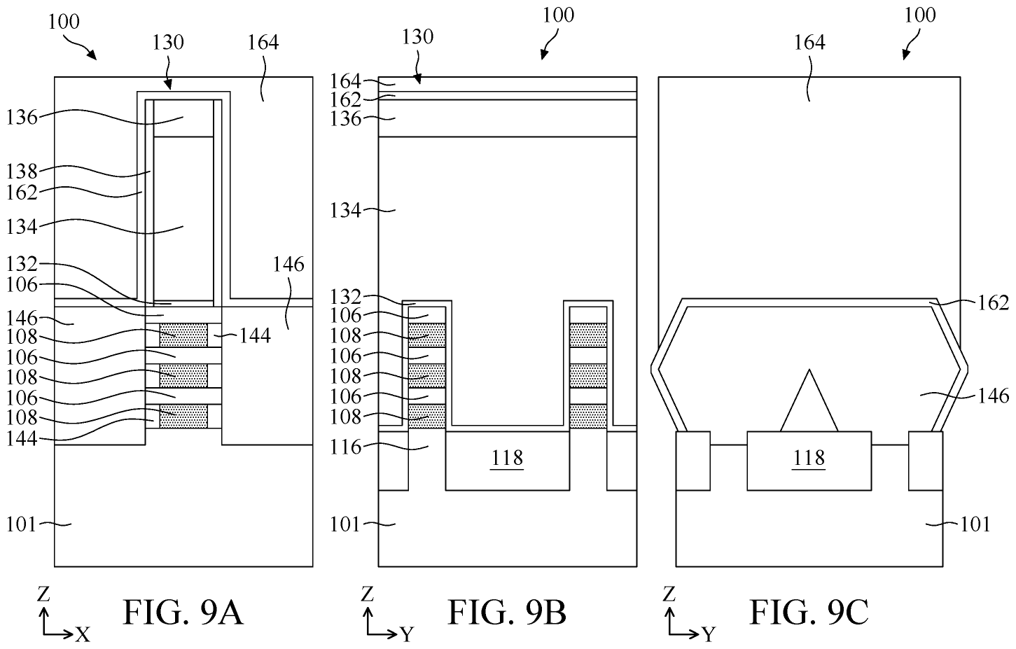

FIGS. 6A, 6B, and 6C are cross-sectional side views of the semiconductor device structure 100 taken along line A-A, line B-B, and line C-C of FIG. 5, respectively. FIGS. 7A-12A and 17A are cross-sectional side views of various stages of manufacturing the semiconductor device structure 100 taken along cross-section A-A of FIG. 6, in accordance with some embodiments. FIGS. 7B-12B and 17B are cross-sectional side views of various stages of manufacturing the semiconductor device structure 100 taken along cross-section B-B of FIG. 5, in accordance with some embodiments. FIGS. 7C-12C and 17C are cross-sectional side views of various stages of manufacturing the semiconductor device structure 100 taken along cross-section C-C of FIG. 5, in accordance with some embodiments. Cross-section A-A is in a plane of the fin structure 112 (channel/fin cut) along the X direction. Cross-section B-B is in a plane perpendicular to cross-section A-A and is in the sacrificial gate structure 130 (gate cut). Cross-section C-C is in a plane perpendicular to cross-section A-A and is in the source/drain region (e.g., epitaxial S/D features 146 shown in FIG. 9A) along the Y-direction.

In FIGS. 7A-7C, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etching process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers (or so-called inner spacer) 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

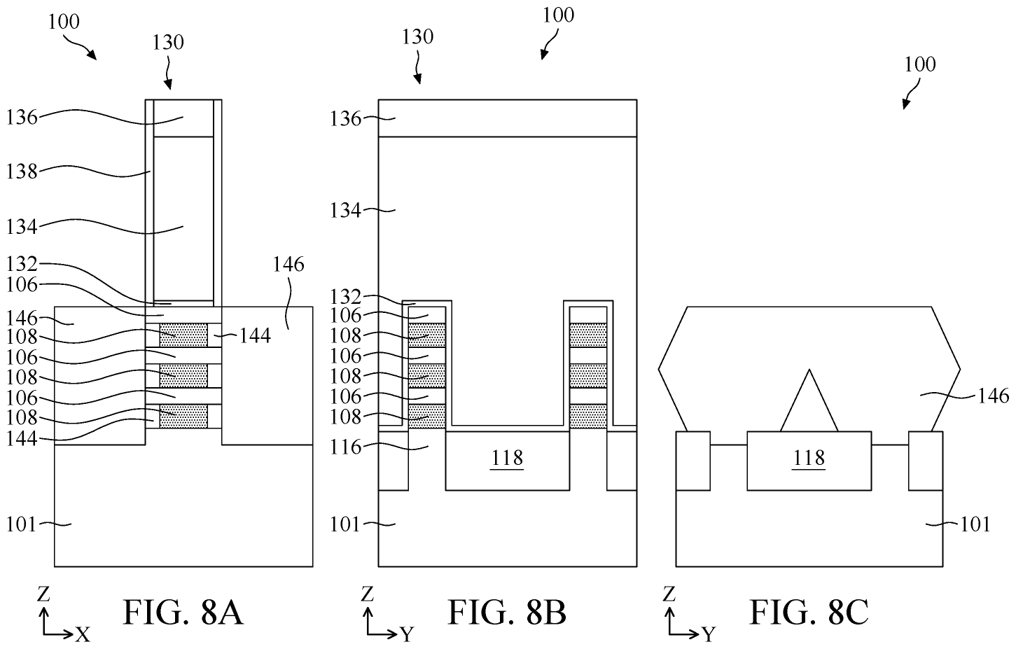

In FIGS. 8A-8C, epitaxial S/D features 146 are formed in the source/drain (S/D) regions. The epitaxial S/D features 146 are formed such that each sacrificial gate structure 130 is disposed between respective neighboring pairs of the S/D regions. In one example shown in FIG. 9A, one of a pair of epitaxial S/D features 146 disposed on one side of the sacrificial gate structure 130 is designated as a source feature/terminal, and the other of the pair of epitaxial S/D features 146 disposed on the other side of the sacrificial gate structure 130 is designated as a drain feature/terminal. The source feature/terminal and the drain feature/terminal are connected by the channel layers (e.g., the first semiconductor layers 106). The epitaxial S/D features 146 are in contact with the first semiconductor layer 106 under the sacrificial gate structure 130. In some cases, the epitaxial S/D features 146 may grow pass the topmost semiconductor channel, i.e., the first semiconductor layer 106 under the sacrificial gate structure 130, to be in contact with the gate spacers 138. The second semiconductor layer 108 under the sacrificial gate structure 130 are separated from the epitaxial S/D features 146 by the dielectric spacers 144.

The epitaxial S/D features 146 may grow both vertically and horizontally to form facets, which may correspond to crystalline planes of the material used for the substrate 101. In some cases, the epitaxial S/D features 146 of a fin structure may grow and merge with the epitaxial S/D features 146 of the neighboring fin structures, as one example shown in FIG. 8C.

The epitaxial S/D features 146 may be made of one or more layers of Si, SiP, SiC and SiCP for n-channel FETs or Si, SiGe, Ge for p-channel FETs. The epitaxial S/D features 146 may be formed by an epitaxial growth method using CVD, ALD or MBE. The epitaxial S/D features 146 may be implanted with dopants followed by an anneal. N-type and/or P-type impurities for epitaxial S/D features 146 may be any of the dopants discussed previously.

In FIGS. 9A-9C, a contact etch stop layer (CESL) 162 is conformally formed on the exposed surfaces of the semiconductor device structure 100. The CESL 162 covers the sidewalls of the sacrificial gate structure 130, the insulating material 118, the epitaxial S/D features 146, and the exposed surface of the stack of semiconductor layers 104. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 164 is formed on the CESL 162 over the semiconductor device structure 100. The materials for the first ILD layer 164 may include compounds comprising Si, O, C, and/or H, such as silicon oxide, TEOS oxide, SiCOH and SiOC. Organic materials, such as polymers, may also be used for the first ILD layer 164. The first ILD layer 164 may be deposited by a PECVD process or other suitable deposition technique. In some embodiments, after formation of the first ILD layer 164, the semiconductor device structure 100 may be subject to a thermal process to anneal the first ILD layer 164.

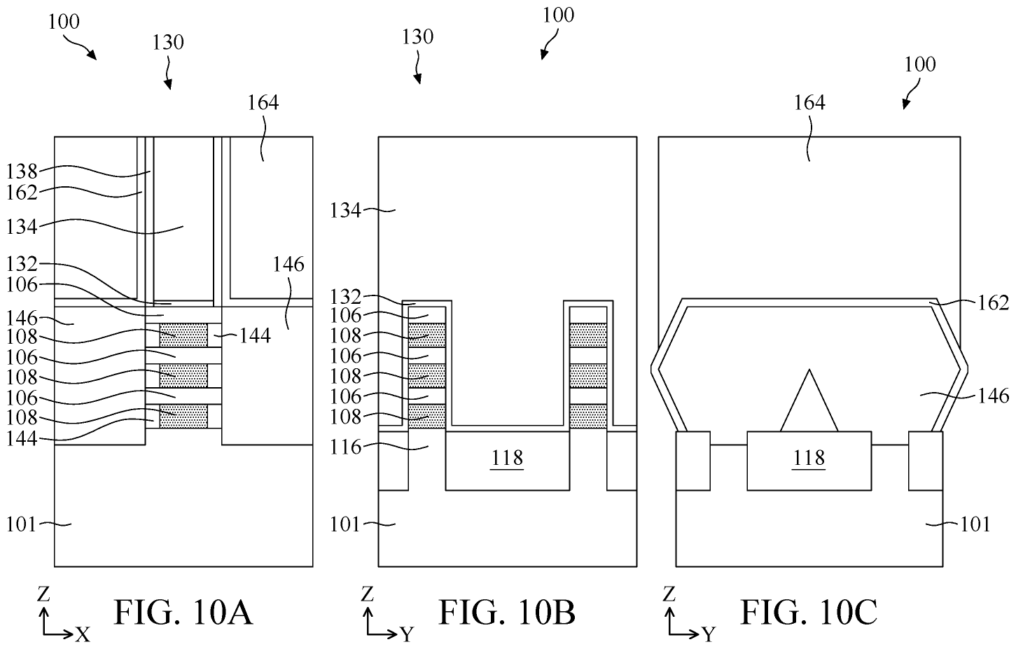

In FIGS. 10A-10C, after the first ILD layer 164 is formed, a planarization operation, such as CMP, is performed on the semiconductor device structure 100 until the sacrificial gate electrode layer 134 is exposed.

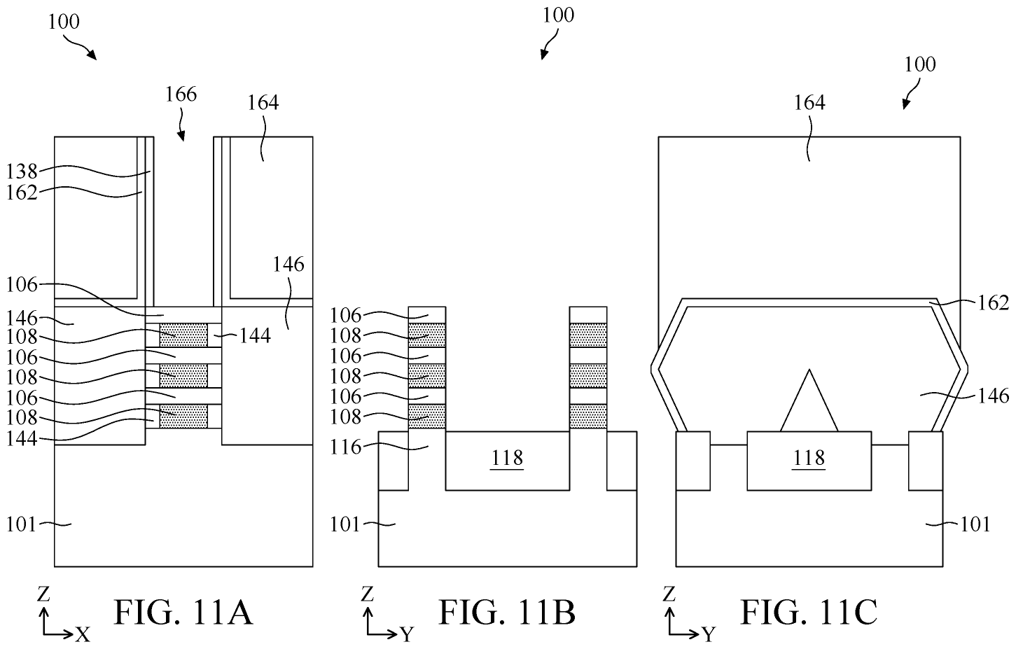

In FIGS. 11A-11C, the sacrificial gate structure 130 is removed. The first ILD layer 164 protects the epitaxial S/D features 146 during the removal of the sacrificial gate structure 130. The sacrificial gate structure 130 can be removed using plasma dry etching and/or wet etching. For example, in cases where the sacrificial gate electrode layer 134 is polysilicon and the first ILD layer 164 is silicon oxide, a wet etchant such as a tetramethylammonium hydroxide (TMAH) solution can be used to selectively remove the sacrificial gate electrode layer 134 without removing the dielectric materials of the first ILD layer 164, the CESL 162, and the gate spacers 138. The sacrificial gate dielectric layer 132 is thereafter removed using plasma dry etching and/or wet etching. The removal of the sacrificial gate structure 130 (i.e., the sacrificial gate electrode layer 134 and the sacrificial gate dielectric layer 132) forms a trench 166 in the regions where the sacrificial gate electrode layer 134 and the sacrificial gate dielectric layer 132 were removed. The trench 166 exposes the top and sides of the stack of semiconductor layers 104 (e.g., the first semiconductor layers 106 and the second semiconductor layers 108).

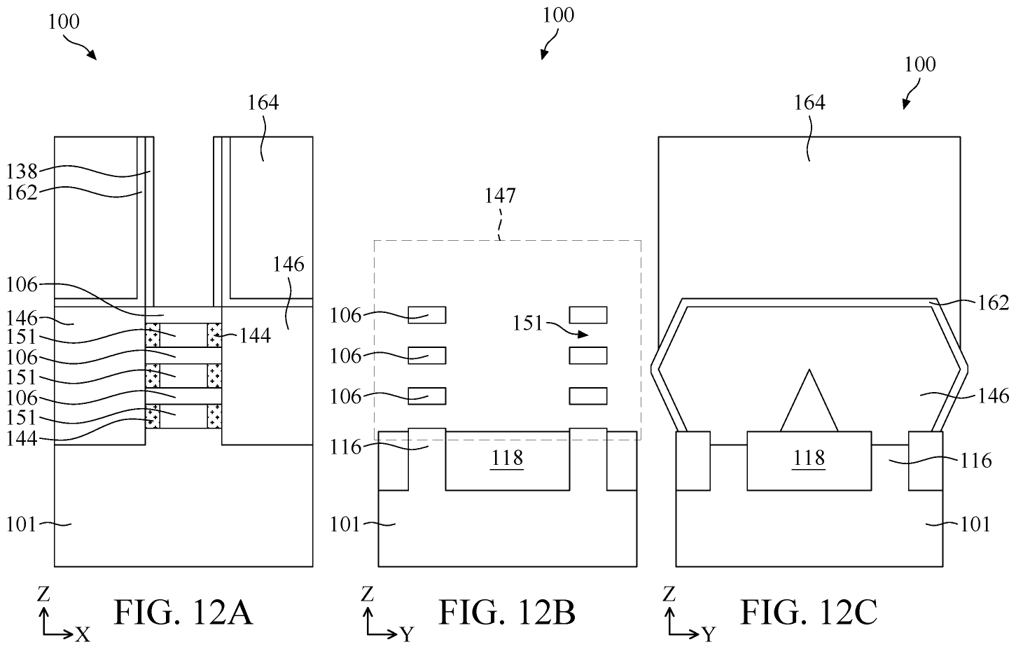

In FIGS. 12A-12C, the exposed second semiconductor layers 108 are removed. The removal of the second semiconductor layers 108 exposes the dielectric spacers 144 and the first semiconductor layers 106. The removal process may be any suitable etch processes, such as dry etch, wet etch, or a combination thereof. The etch process may be a selective etch process that removes the second semiconductor layers 108 but without substantially attacking the first semiconductor layers 106. In some embodiments, the etch process is an isotropic etching process using an etching gas, and optionally, a carrier gas, where the etching gas comprises F₂ and HF, and the carrier gas may be an inert gas such as Ar, He, N₂, combinations thereof, or the like. Upon removal of the second semiconductor layers 108, openings 151 are formed around the first semiconductor layers 106, and the portion of the first semiconductor layers 106 not covered by the dielectric spacers 144 is exposed to the openings 151. The remaining first semiconductor layers 106 may serve as channel regions for the GAA devices, which may include at least an NFET or a PFET in some embodiments. While not specifically shown, one of the GAA devices, such as the semiconductor device structure 100, may be an NFET or a PFET, in accordance with some embodiments.

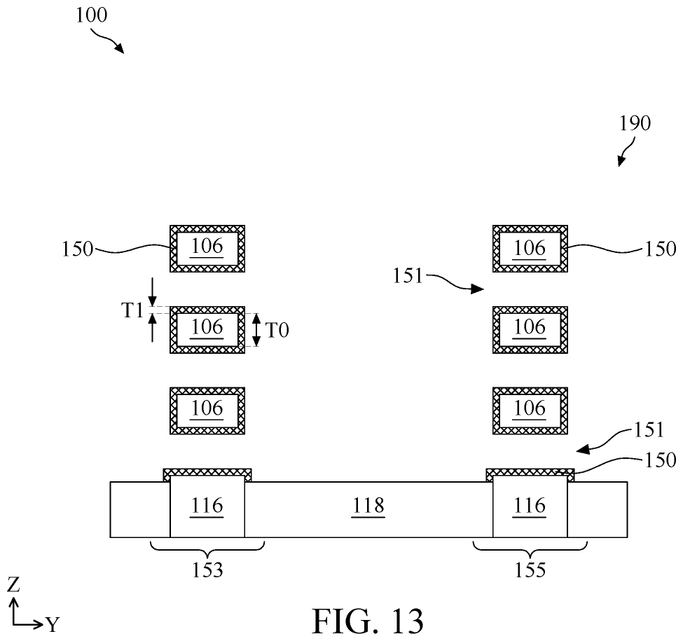

FIGS. 13-16 are enlarged views of a region 147 of FIG. 12B showing various stages of manufacturing replacement gate structure 190 for the semiconductor device structure 100, in accordance with some embodiments. As discussed above, the substrate 101 may include various regions that have been doped with impurities (e.g., dopants having P-type or N-type conductivity). In various embodiments, the substrate 101 has a region 153 and a region 155 adjacent to the region 153. The region 153 may be designated as a P-type region or an N-type region, and the region 155 may be designated as an N-type region or a P-type region. Alternatively, both regions 153, 155 may be designated as a P-type region or N-type region. In one embodiment, the region 153 is an N-type region and the region 155 is a P-type region. While not shown in scale in some figures, the region 153 and the region 155 belong to a continuous substrate 101. In some embodiments of the present disclosure, the P-type region is used to form a PMOS structure thereon, whereas the N-type region is used to form an NMOS structure thereon. Depending on circuit design, the regions 153, 155 may be used for forming different types of circuits. For example, the region 153 may be used for forming, e.g., peripheral circuits, input/output (I/O) circuits, electrostatic discharge (ESD) circuits, and/or analog circuits and the region 155 region may be used for forming logic circuits. Other regions for forming other types of circuits are contemplated and are intended to be included within the scope of the present disclosure.

In FIG. 13, an interfacial layer (IL) 150 is formed to surround the exposed surfaces of the first semiconductor layers 106. In some embodiments, the IL 150 may also form on the well portion 116 of the substrate 101. The IL 150 may include or be made of an oxygen-containing material or a silicon-containing material, such as silicon oxide, silicon oxynitride, oxynitride, etc. In one embodiment, the IL 150 is silicon oxide. The IL 150 may be formed by first subjecting the first semiconductor layers 106 and the exposed well portion 116 of the substrate 101 to a wet process. The wet process may be any suitable wet cleaning process or self-compensation wet process. In some embodiments, the wet process is an etch process using at least ozone (03) and/or ammonium hydroxide (NH₄OH). For example, the wet process may include NH₄OH, HF or diluted HF, deionized (DI) water, tetramethylammonium hydroxide (TMAH), other suitable wet etching solution, or a combination thereof. In one embodiment, the wet process may be a standard clean-2 (SC2) followed by a standard clean-1 (SC1), where the SC2 is a mixture of DI water, hydrochloric (HCl) acid, and hydrogen peroxide (H₂O₂), and the SC1 is a mixture of D1 water, NH₄OH, and H₂O₂. In some embodiments, an isopropyl alcohol (IPA) may be used after the SC1. Other suitable wet cleaning process, such as an APM process, which includes at least water (H₂O), ammonium hydroxide (NH₄OH), and hydrogen peroxide (H₂O₂), a HPM process, which includes at least H₂O. H₂O₂, and hydrogen chloride (HCl), a SPM process (also known as piranha clean), which includes at least H₂O₂ and sulfuric acid (H₂SO₄), or any combination thereof, may also be used.

Additionally or alternatively, the IL 150 may be formed by a wet oxidation process, which oxidizes an outer portion of the first semiconductor layers 106 and an outer portion of the exposed well portion 116 of the substrate 101. That is, the outer portion of the first semiconductor layers 106 and the exposed well portion 116 of the substrate 101 is or part of the IL 150. The outer portion surrounds and in contact with the first semiconductor layers 106 and the well portion 116 of the substrate 101 upon completion of the oxidation. In some embodiments, the IL 150 may be formed using an oxidation process such as thermal oxidation process, a rapid thermal oxidation (RTO) process, an in-situ stream generation (ISSG) process, or an enhanced in-situ stream generation (EISSG) process. In one example, the IL 150 is formed by subjecting the first semiconductor layers 106 and the well portion 116 of the substrate 101 to a rapid thermal anneal (RTA) in an oxygen-containing environment. The thermal oxidation may be performed at a temperature of about 600 degrees Celsius to about 1100 degrees Celsius, for a time span of about 10 seconds to about 30 seconds. The temperature and time span of the oxidation may contribute to the thickness of the IL 150. For example, higher temperatures and longer oxidation time spans may result in a thicker IL 150. Alternatively, the IL 150 may also be an oxide formed by CVD, ALD or any suitable conformal deposition technique.

The IL 150 has a uniform thickness on the exposed surfaces of the first semiconductor layers 106 and on the well portion 116 of the substrate 101. In some embodiments, the IL 150 has a thickness T1 and the first semiconductor layer 106 has a thickness T0, and a ratio of the T1:T0 is in a range of about 1:5 to about 1:30.

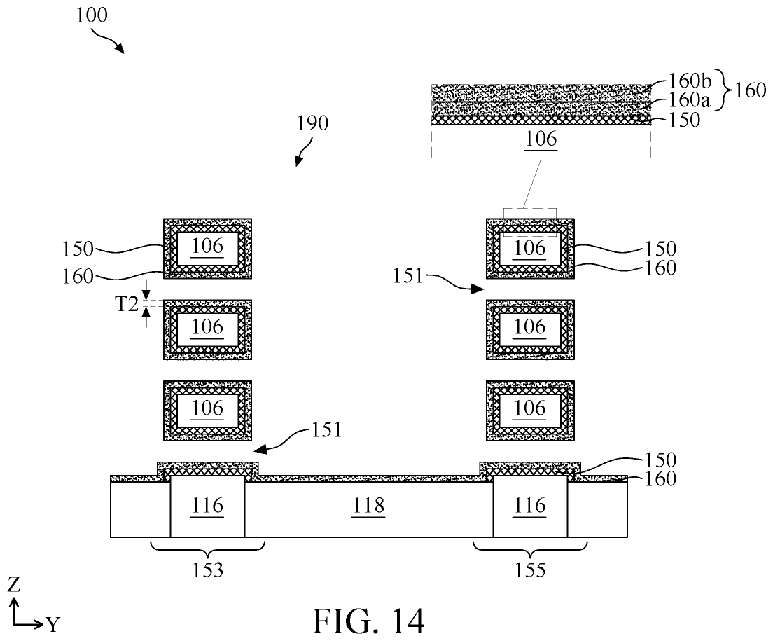

In FIG. 14, a high-K (HK) dielectric layer 160 is formed on the exposed surfaces of the semiconductor device structure 100. In some embodiments, the HK dielectric layer 160 is formed to wrap around and in contact with the IL 150. The HK dielectric layer 160 is also formed on the exposed surface of the insulating material 118. The HK dielectric layer 160 may be a single layer or a multi-layer structure. In one embodiment, the HK dielectric layer 160 is a bi-layer structure including a first HK dielectric layer 160a and a second HK dielectric layer 160b. The first and second HK dielectric 160a, 160b may use a material chemically different from each other. Suitable materials for the HK dielectric layer 160 may include, but are not limited to, hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium oxide (ZrO), titanium oxide (TiO), tantalum oxide (Ta₂O₅), yttrium oxide (Y₂O₃), silicon oxynitride (SiON), or the like, or any material having a dielectric constant value greater than a dielectric constant of silicon oxide. The HK dielectric layer 160 may be a conformal layer formed by a conformal process, such as an ALD process or a CVD process. The HK dielectric layer 160 may have a thickness T2 ranging from about 10 Angstroms to about 50 Angstroms.

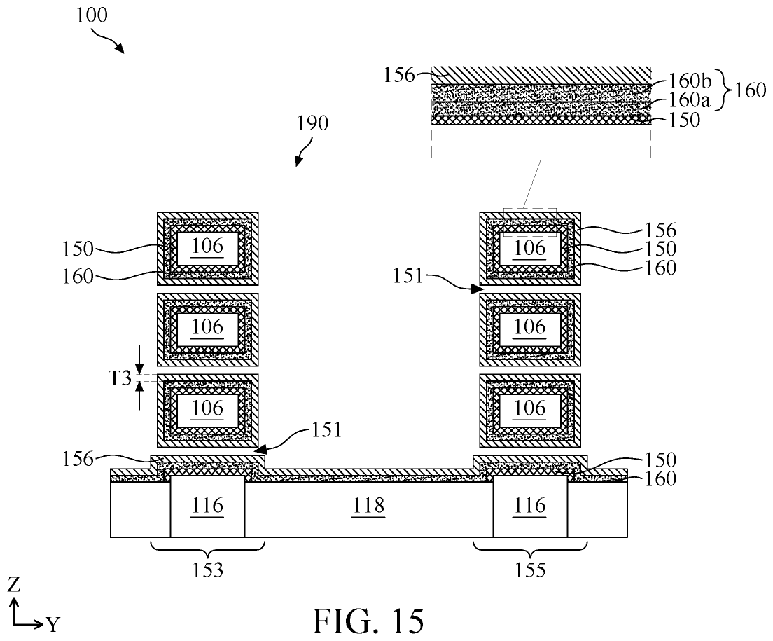

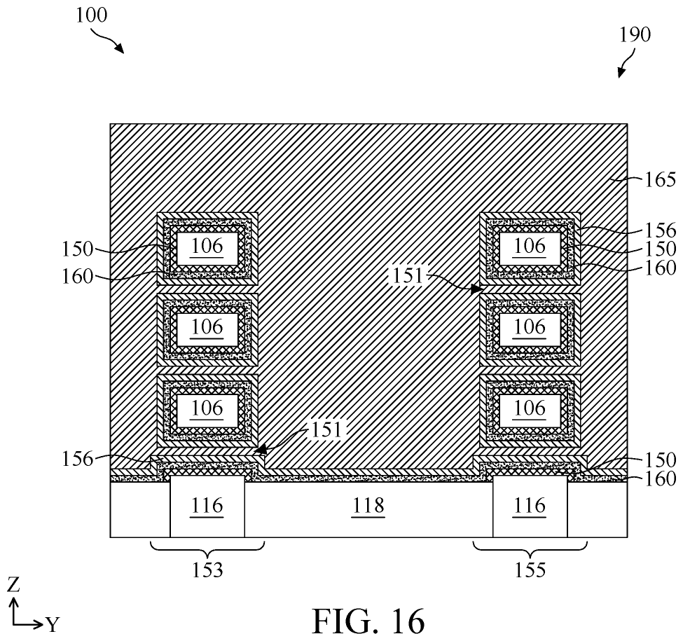

In FIG. 15, an insertion layer 156 is formed on the HK dielectric layer 160. The insertion layer 156 is conformally formed over the HK dielectric layer 160. In embodiments where the HK dielectric layer 160 is a bi-layer structure, the insertion layer 156 is formed on and in contact with a top of the second HK dielectric 160b, as an enlarged view of a portion of the semiconductor device structure 100 shown in FIG. 15. The insertion layer 156 serves as an oxygen barrier that blocks oxygen migration from the HK dielectric layer 160 to a subsequently formed metal gate (e.g., gate electrode layer 165, FIG. 16). The insertion layer 156 can keep oxygen in insulators (i.e., HK dielectric layer 160 and IL 150) to reduce generation of oxygen vacancies in the HK dielectric layer 160, prevent the metal gate from increasing the resistivity thereof due to oxidation, and promote stress relaxation of the channel regions. Since generation of oxygen vacancies is suppressed by the insertion layer 156, the number of thermal treatments for repairing oxygen vacancies can be reduced or even eliminated, thereby avoiding thickening of the IL 150 (due to IL re-growth) and diffusion of dopants in source/drain features. The IL 150 being too thick consumes gate fill window, which may increase the resistance of the device and also affect the ability of threshold voltage tuning. By forming the insertion layer 156 between the HK dielectric layer 160 and the metal gate, the overall reliability of the device is improved, and a large gate fill window can be maintained.

The insertion layer 156 may include or be formed of a noble metal or semi-noble metal, such as gold (Au), platinum (Pt), iridium (Ir), palladium (Pd), osmium (Os), silver (Ag), rhodium (Rh), ruthenium (Ru), or the like. In some embodiments, the insertion layer 156 is a single layer of pure noble metal, or nearly pure noble metal with less than 0.01% of impurities. In some embodiments, the insertion layer 156 may include noble metal oxide that is electrically conductive, such as ruthenium oxide (RuO₂). In some embodiments, the insertion layer 156 may include tungsten nitride (WN), titanium nitride (TiN), or the like. The insertion layer 156 may be a multi-layer structure including two or more materials discussed herein. For example, the insertion layer 156 may include a first layer containing a noble metal and a second layer containing a noble metal oxide. The insertion layer 156 may be formed by ALD, PVD, CVD, or any other suitable technique. The insertion layer 156 may have a thickness T3 in a range of about 2 Angstroms to about 10 Angstroms. If the thickness T3 of the insertion layer 156 is less than about 2 Angstroms, the insertion layer 156 may not function as intended for effective blocking of oxygen. On the other hand, if the thickness T3 of the insertion layer 156 is more than 10 Angstroms, the gate fill window will be negatively affected.

In FIG. 16, a gate electrode layer 165 is formed on the insertion layer 156. The gate electrode layer 165 wraps around a portion of each first semiconductor layer 106 and filles the opening 151 (FIG. 15) at the region 153, 155. The gate electrode layer 165 may be deposited so that at least the nanosheet transistors at the regions 153, 155 are submerged in the gate electrode layer 165. In some embodiments, the gate electrode layer 165 is deposited to a height over a top surface of the insertion 156 over the first semiconductor layer 106. In some embodiments, the gate electrode layer 165 may be formed using multiple layers, each layer deposited sequentially adjacent to each other using a highly conformal deposition process such as ALD. Other deposition technique such as PVD, CVD, or electro-plating may also be used. While not shown, the gate electrode layer 165 may include a capping layer, a barrier layer, an n-metal work function layer, a p-metal work function layer, and a fill material. The capping layer and the barrier layer may be metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be formed of a material different from the capping layer. The n-metal work function layer may be formed from a metallic material such as W, Cu, AlCu, TiAlC, TiAlN, Ti, TiN, Ta, TaN, Co, Ni, Ag, Al, TaAl, TaAlC, TaC, TaCN, TaSiN, Mn, Zr, other suitable n-type work function materials, or combinations thereof. The p-metal work function layer may be formed from a metallic material such as W. Al, Cu, TiN, Ti, TiAlN, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Once the n-metal work function layer and the p-metal work function layer are formed, the fill material is deposited to fill a remainder of the opening 151. The fill material may be a material such as W, Al, Cu, AlCu, W, Ti, TiAlN, TaC, TaCN, TaSiN, Mn, Zr, TiN, Ta, TaN, Co, Ni, combinations of these, or the like.

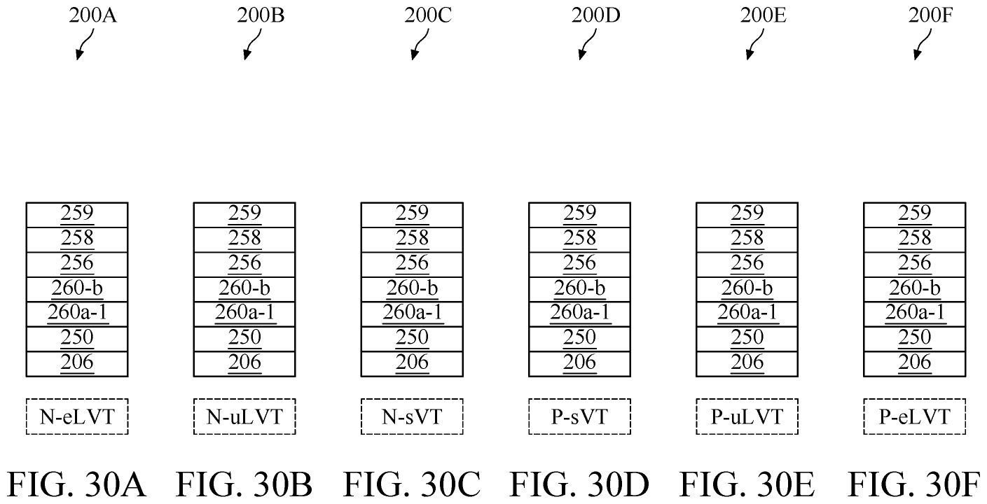

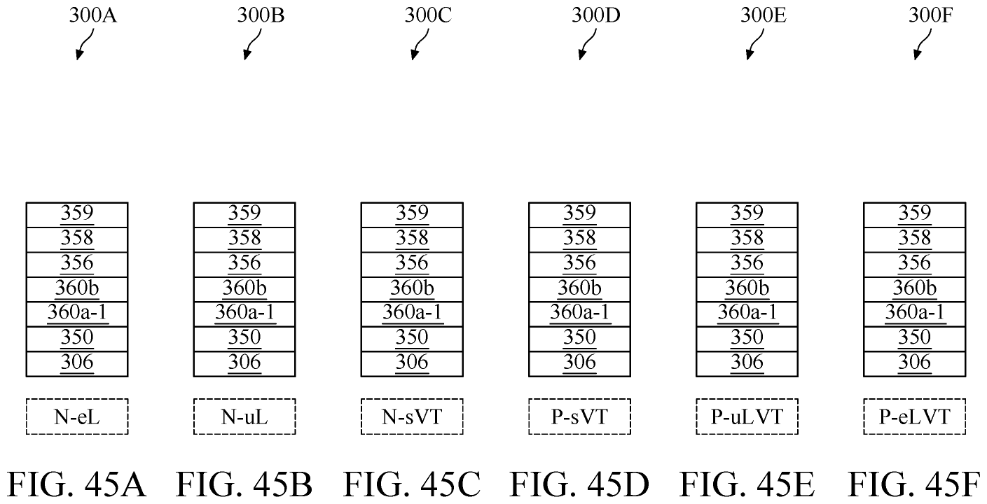

In some embodiments, the gate electrode layer 165 may include the same material as metal layer 258 (FIGS. 30A-30F) or metal layer 358 (FIG. 45A-45F), as will be discussed in more detail below.

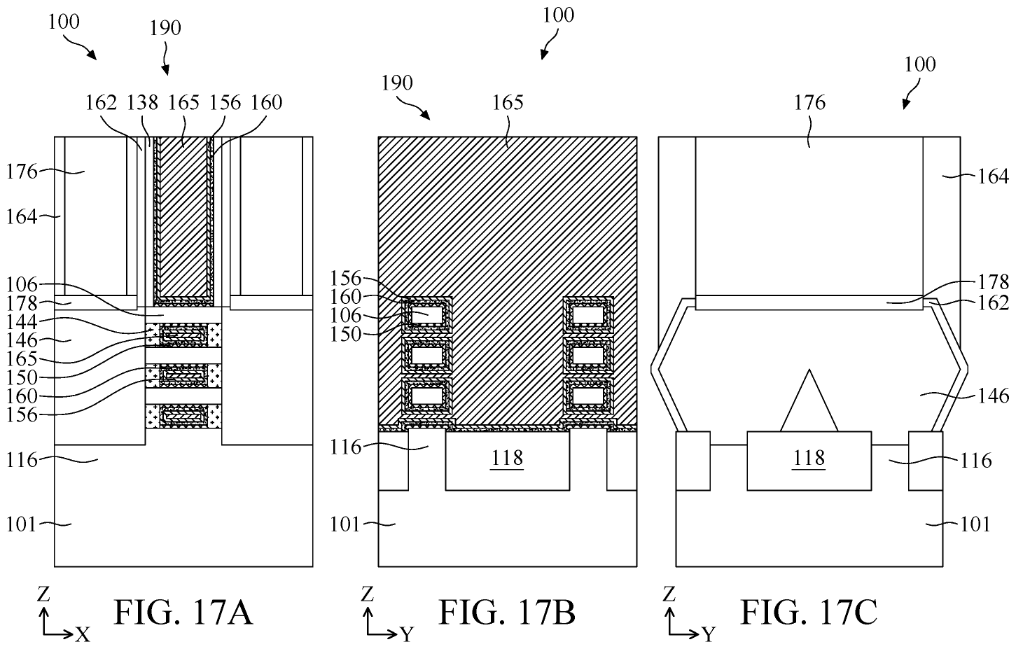

In FIGS. 17A-17C, contact openings are formed through the ILD layer 164 and the CESL 162 to expose the epitaxial S/D feature 146. A silicide layer 178 is then formed on the epitaxial S/D features 146 to conductively couple the epitaxial S/D features 146 to the subsequently formed S/D contacts 176. The silicide layer 178 may be formed by depositing a metal source layer over the epitaxial S/D features 146 and performing a rapid thermal annealing process. The metal source layer includes a metal layer selected from W, Co, Ni, Ti, Mo, and Ta, or a metal nitride layer selected from tungsten nitride, cobalt nitride, nickel nitride, titanium nitride, molybdenum nitride, and tantalum nitride. During the rapid anneal process, the portion of the metal source layer over the epitaxial S/D features 146 reacts with silicon in the epitaxial S/D features 146 to form the silicide layer 178. Unreacted portion of the metal source layer is then removed.

After formation of the silicide layer 178, a conductive material is formed in the contact openings and form the S/D contacts 176. The conductive material may be made of a material including one or more of Ru, Mo, Co, Ni, W, Ti, Ta, Cu, Al, TiN and TaN. While not shown, a barrier layer (e.g., TiN, TaN, or the like) may be formed on sidewalls of the contact openings prior to forming the S/D contacts 176. Then, a planarization process, such as CMP, is performed to remove excess deposition of the contact material and expose the top surface of the gate electrode layer 165.

It is understood that the semiconductor device structure 100 may undergo further complementary metal oxide semiconductor (CMOS) and/or back-end-of-line (BEOL) processes. For example, gate contacts may be formed to electrically couple to the gate electrode layer 165. An interconnect structure may be formed over the S/D contacts 176 and gate contacts. The interconnect structure may include a plurality of dielectric layers and metallic features, including conductive traces and conductive vias, embedded in the dielectric layers, which form electrical connection between various devices on the substrate 101. The semiconductor device structure 100 may also include backside contacts (not shown) on the backside of the substrate 101 by flipping over the semiconductor device structure 100, removing the substrate 101, and selectively connecting source or drain feature/terminal of the epitaxial S/D features 146 to a backside power rail (e.g., positive voltage VDD or negative voltage VSS) through the backside contacts. Depending on the application, the source or drain feature/terminal of the epitaxial S/D features 146 and the gate electrode layer 172 may be connected to a frontside power source.

In some embodiments, the insertion layer (i.e., oxygen barrier) discussed above may be combined with N-dipole or P-dipole process for simplification of process difficulty, increase of throughput (i.e., productivity), and reduction of cost. The combination of oxygen barrier (e.g., insertion layer 156) with N-dipole or P-dipole processes helps to achieve a single P-edge work-function metal knob (i.e., a single film process) or a single N-edge work-function metal knob in advanced technology nodes.

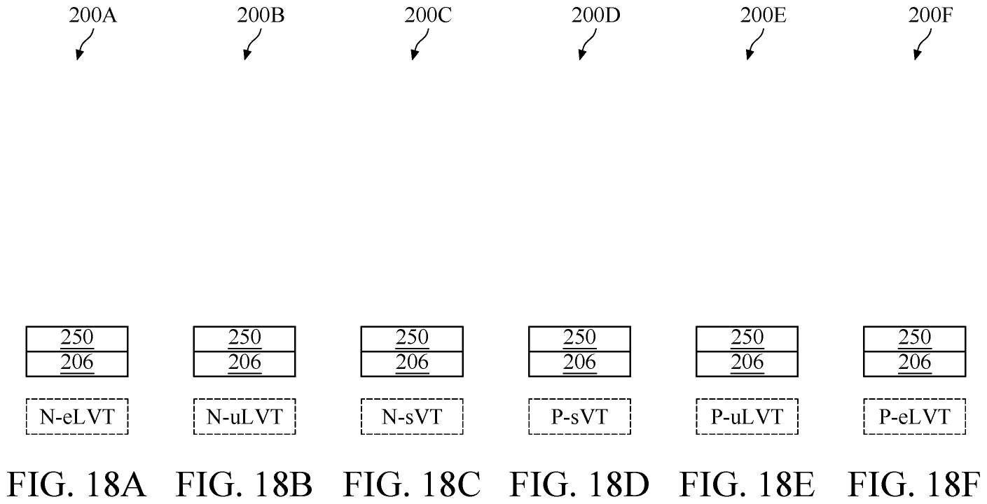

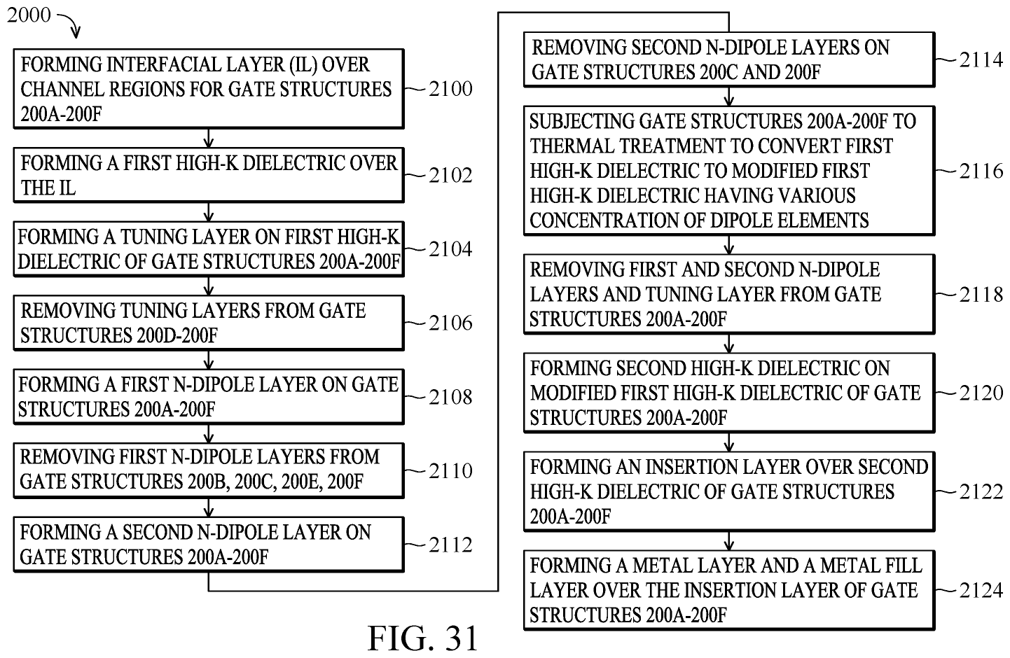

FIGS. 18A through 30F illustrate formation of gate structures 200A-200F for a semiconductor device 201, such as a multiple threshold voltage GAA FET structure, in accordance with various embodiments. FIG. 31 illustrates a flowchart of a process 2000 for forming the gate structures 200A-200F shown in FIGS. 18A-30F, in accordance with various embodiments. The FIGS. 18A-30A illustrate formation of a transistor having an N-type extreme low threshold voltage (N-eLVT) gate structure, such as the gate structure 200A. FIGS. 18B-30B illustrate formation of a transistor having an N-type ultra low threshold voltage (N-uLVT) gate structure, such as the gate structure 200B. FIGS. 18C-30C illustrate formation of a transistor having an N-type standard threshold voltage (N-sVT) gate structure, such as the gate structure 200C. FIGS. 18D-30D illustrate formation of a transistor having a P-type standard threshold voltage (P-sVT) gate structure, such as the gate structure 200D. FIGS. 18E-30E illustrate formation of a transistor having a P-type ultra low threshold voltage (P-uLVT) gate structure, such as the gate structure 200E. FIGS. 18F-30F illustrate formation of a transistor having a P-type extreme low threshold voltage (P-eLVT) gate structure, such as the gate structure 200F. The gate structures 200A-200F may be applied to FinFETs, GAA FETs, CFETs, forksheet FETs, vertical FETs, etc.

A transistor having an N-type standard threshold voltage (N-sVT) gate structure may need a threshold voltage at a first value to create a conducting path between source and drain terminals, a transistor having an N-type ultra low threshold voltage (N-uLVT) gate structure may need a threshold voltage at a second value threshold voltage to create a conducting path between source and drain terminals, and a transistor having an N-type extreme low threshold voltage (N-eLVT) gate structure may need a threshold voltage at a third value threshold voltage to create a conducting path between source and drain terminals. In some cases, the first value is greater than the second value, and the second value is greater than the third value.

Likewise, a transistor having a P-type standard threshold voltage (P-sVT) gate structure may need a threshold voltage at a fourth value threshold voltage to create a conducting path between source and drain terminals, a transistor having a P-type ultra low threshold voltage (P-uLVT) gate structure may need a threshold voltage at a fifth value threshold voltage to create a conducting path between source and drain terminals, and a transistor having a P-type extreme low threshold voltage (P-eLVT) gate structure may need a threshold voltage at a sixth value threshold voltage to create a conducting path between source and drain terminals. In some cases, the fourth value is greater than the fifth value, and the fifth value is greater than the sixth value.

The gate structures 200A-200F may be formed on the same wafer and/or may be parts of the same IC device in some embodiments. As such, at least some of the fabrication processes discussed below may be performed to all the gate structures 200A-200F simultaneously. In FinFET embodiments, the gate structures 200A-200F each wrap around at least three surfaces of the fin structures (e.g., channel layer). In GAA FET embodiments, the gate structures 200A-200F may wrap around channel regions of the fin structures entirely.

At block 2100, the gate structures 200A-200F are shown at an intermediate stage of fabrication, such as the stage shown in FIG. 12B, where the sacrificial gate structure and the second semiconductor layers 108 have been removed to expose portions of the first semiconductor layers 106. As can be seen in FIGS. 18A-18F, each gate structure 200A-200F includes an IL 250 formed over first semiconductor layers 206 (i.e., channel regions), such as the first semiconductor layer 106 of the semiconductor device structure 100 shown in FIGS. 12A and 12B. Only a fragmentary portion of the first semiconductor layers 206 is illustrated for the sake of simplicity. In some embodiments, the IL 250 includes an oxide of the semiconductor material of the substrate 101, such as silicon oxide. In other embodiments, the IL 250 may include another suitable type of dielectric material. The IL 250 may be formed by a wet process or a wet oxidation process as those discussed above with respect to FIG. 13 for forming the IL 150. The IL 250 may have a thickness in a range between about 5 angstroms and about 50 angstroms, such as about 7 angstroms to about 10 angstroms.

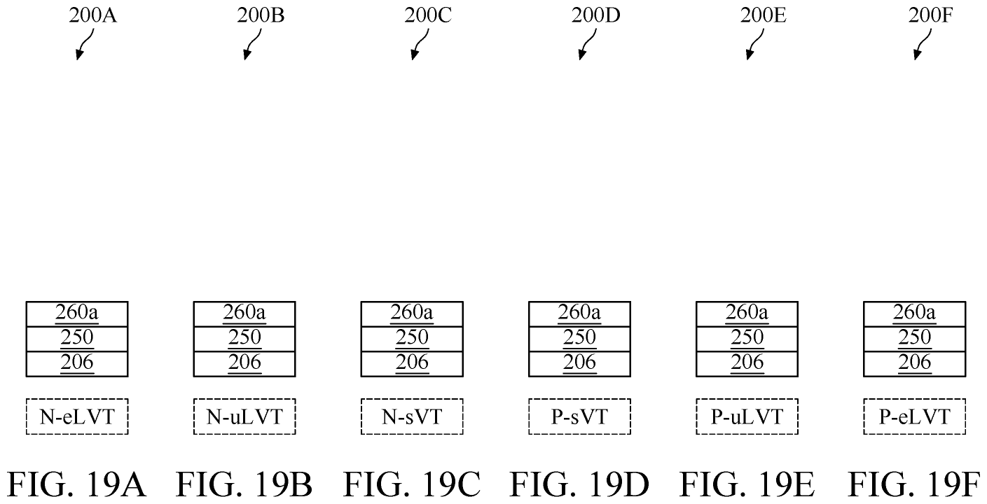

At block 2102, a first high-K (HK) dielectric 260a is formed over the IL 250, as shown in FIGS. 19A-19F. The first HK dielectric 260a may include the same material as the first HK dielectric 160a as discussed above with respect to FIG. 14. In some embodiments, the first HK dielectric layer 260a is formed by an ALD process to control thickness of the deposited layer with precision. The ALD process may be performed using between about 20 and about 40 deposition cycles, at a temperature range between about 200 degrees Celsius and about 300 degrees Celsius. In some embodiments, the ALD process uses HfCl₄ and/or H₂O as precursors. Such an ALD process may form the first HK dielectric 260a to have a thickness in a range of about 5 Angstroms to about 15 Angstroms.

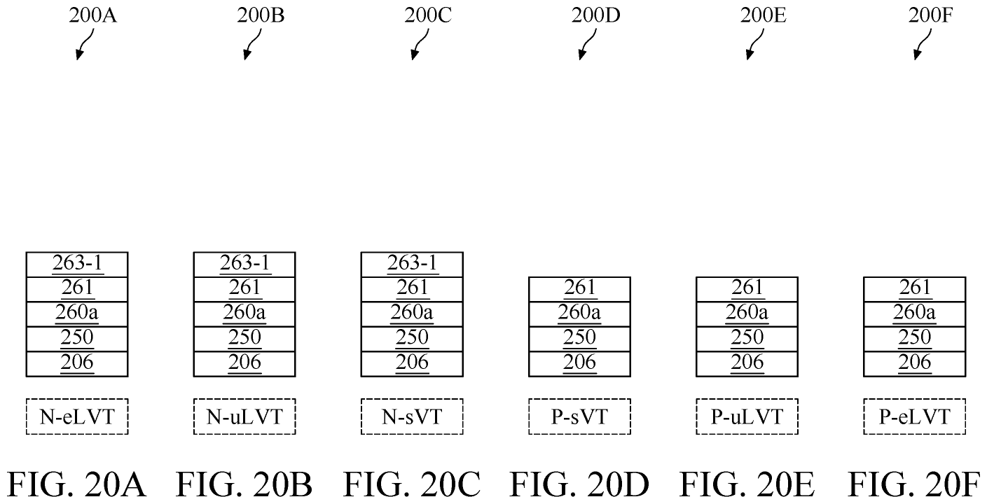

At block 2104, a tuning layer 261 is formed on the first HK dielectric 260a of the gate structures 200A-200F, and a patterned resist layer 263-1 is formed over the gate structures 200A, 200B, 200C, as shown in FIG. 20A-20F. The tuning layer 261 allows for subsequent tuning of threshold voltage in the gate structures 200A, 200B, 200C. The tuning layer 261 is deposited directly on the first HK dielectric 260a in the gate structures 200A-200F. The tuning layer 261 may be a dielectric material containing dipole element(s) suitable for Vth tuning for N-type devices. The tuning layer 261 may be an oxide-based or non-oxide based dielectric material. In some embodiments, the tuning layer 261 is a metal oxide material, in which the metal may include, but is not limited to, lanthanum (La), lutetium (Lu), scandium (Sc), yttrium (Y), thulium (Tm), gadolinium (Gd), magnesium (Mg), or combinations thereof. Exemplary metal oxide for the tuning layer 261 may include La₂O₃, LuOₓ, ScOₓ, Y₂O₃, Tm₂O₃, Gd₂O₃, MgO, or the like. The tuning layer 261 may be formed using a conformal deposition process, such as an ALD process. For the gate structures 200A-200C, the tuning layer 261 may increase or compensate for the threshold voltage Vth needed for N-type transistor devices. The tuning layer 261 may have a thickness in a range between about 3 Angstroms and about 12 Angstroms, for example about 5 Angstroms to about 8 Angstroms. If the thickness of the tuning layer 261 is less than 3 Angstroms, the tuning layer 261 may not be sufficient to provide required tuning effect for the N-type devices. On the other hand, if the thickness of the tuning layer 261 is greater than about 12 Angstroms, the room left for the subsequent layers may be reduced and the manufacturing cost is increased without significant advantage.

After the tuning layers 261 are deposited on the gate structures 200A-200F, a patterned resist layer 263-1 is formed to cover gate structures for N-type FETs, such as the gate structures 200A-200C, while gate structures for P-type FETs, such as gate structures 200D-200F, are left uncovered. The patterned resist layer 263-1 protects the tuning layer 261 on the gate structures 200A-200C so that the tuning layer 261 on the gate structures 200D-200F can be removed. The patterned resist layer 263-1 may be formed by first forming a blanket layer over the gate structures 200A-200F, followed by patterning and etching processes to remove portions of the blanket layer at selected regions (e.g., regions where gate structures 200D-200F are located) to form the patterned resist layer 263-1. The patterned resist layer 263-1 may be any suitable masking material, such as a photoresist layer, a BARC (bottom anti-reflective coating) layer, a SOG (spin-on-glass) layer, or a SOC (spin-on-carbon) layer, and may be deposited by spin coating or any suitable deposition technique.

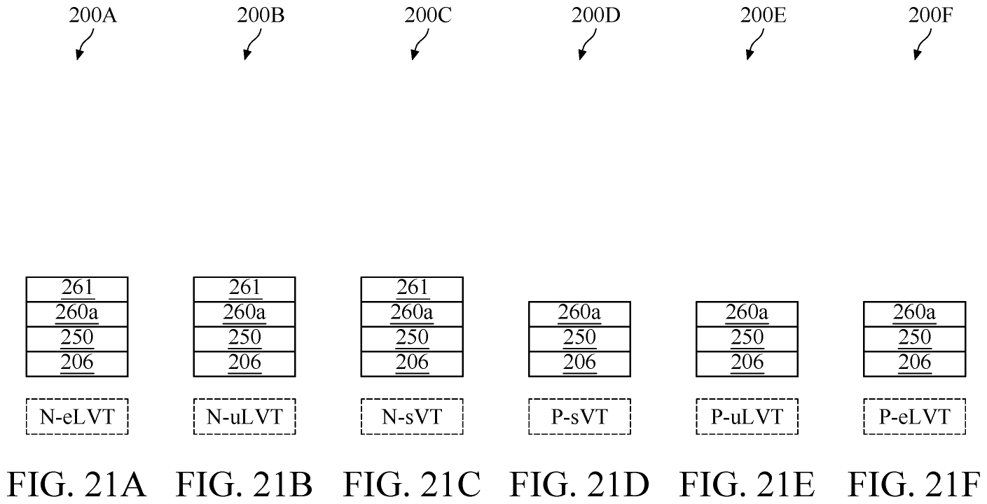

At block 2106, once the patterned resist layer 263-1 is formed, the tuning layers 261 on the gate structures 200D-200F are removed, and then the patterned resist layer 263-1 is removed, as shown in FIGS. 21A-21F. The tuning layers 261 may be removed, using the patterned resist layer 263-1 as a mask, by any suitable etch process, such as a dry etch, a wet etch, or a combination thereof. In some embodiments, an etchant used in such an etch process may include hydrochloric acid (HCl), alkali (NH₄), oxidant, or other suitable etchant. The patterned resist layer 263-1 may be removed using any suitable process, such as an ashing process.

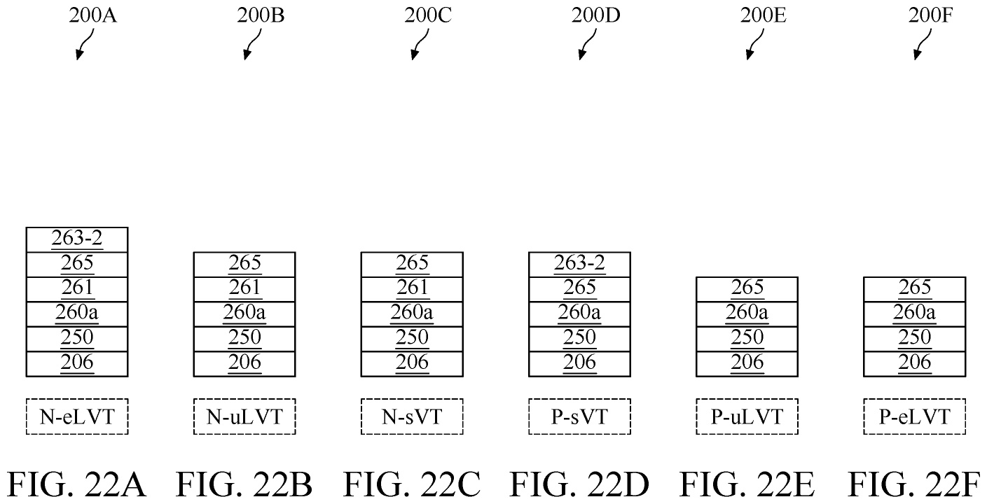

At block 2108, a first N-dipole layer 265 is globally formed on the gate structures 200A-200F, and a patterned resist layer 263-2 is formed on the first N-dipole layer 265 of the gate structures 200A and 200D, as shown in FIGS. 22A-22F. The first N-dipole layer 265 is formed on the tuning layers 261 of the gate structures 200A-200C, and on the first HK dielectric 260a of the gate structures 200D-200F. The first N-dipole layer 265 is a material inherently including a negative polarity. In some embodiments, the first N-dipole layer 265 is a dielectric material containing dipole element(s) suitable for N-type devices. The first N-dipole layer 265 may be selected from the material used for the tuning layer 261. In some embodiments, the first N-dipole layer 265 may include the same material as the tuning layer 261. In some embodiments, the first N-dipole layer 265 may include a material that is chemically different than the tuning layer 261. Exemplary material for the first N-dipole layer 265 may include La₂O₃, LuOₓ, ScOₓ, Y₂O₃, Tm₂O₃, Gd₂O₃, MgO, or the like. For the gate structures 200A-200C, the first N-dipole layer 265 may increase the threshold voltage Vth needed for N-type transistor devices. For the gate structures 200D-200F corresponding to P-type transistor devices, the first N-dipole layer 265 may decrease the threshold voltage Vth for P-type transistor devices.

The first N-dipole layer 265 may be formed using a conformal deposition process, such as an ALD process. The tuning layer 261 may be deposited using a first cycle number of ALD process and the first N-dipole layer 265 may be deposited using a second cycle number of ALD process less than the first cycle number. As such, the tuning layer 261 has a thickness greater than that of the first N-dipole layer 265. Each of the first N-dipole layers 265 may have a thickness in a range between about 1 Angstroms and about 6 Angstroms, for example about 2 Angstroms to about 3 Angstroms.

After the first N-dipole layers 265 are formed on the gate structures 200A-200F, the patterned resist layer 263-2 is formed to cover certain gate structures for N-type FETs and P-type FETs, such as the gate structures 200A and 200D, while gate structures for certain N-type FETs and P-type FETs, such as gate structures 200B, 200C, 200E, and 200F, are left uncovered. The patterned resist layer 263-2 protects the first N-dipole layers 265 on the gate structures 200A and 200D so that the first N-dipole layers 265 on the gate structures 200B, 200C, 200E, and 200F can be removed. The patterned resist layer 263-2 may be formed in a similar fashion to those discussed above with respect to the patterned resist layer 263-1.

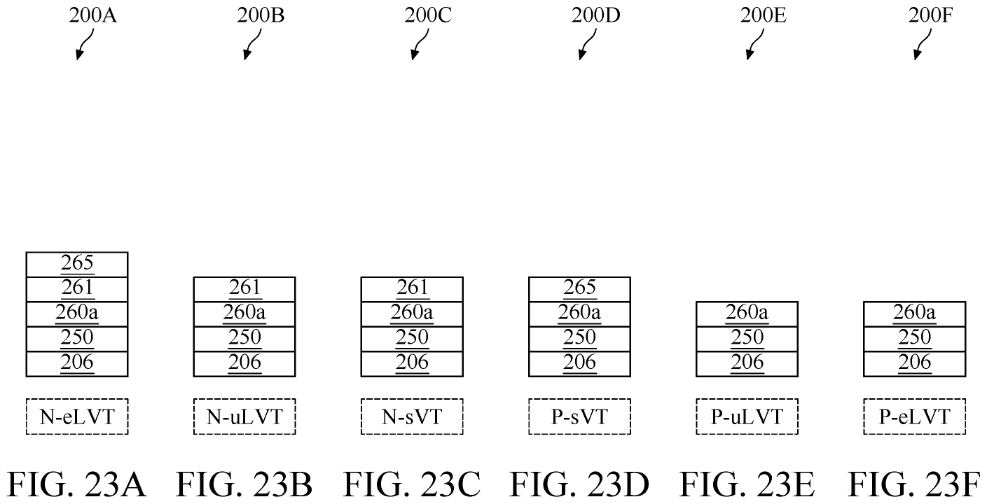

At block 2110, the first N-dipole layers 265 on the gate structures 200B, 200C, 200E, and 200F are removed, and then the patterned resist layer 263-2 is removed, as shown in FIGS. 23A-23F. The first N-dipole layers 265 may be removed, using the patterned resist layer 263-2 as a mask, by any suitable etch process, such as those discussed above for removing the tuning layer 261. The patterned resist layer 263-2 may be removed using any suitable process, such as an ashing process.

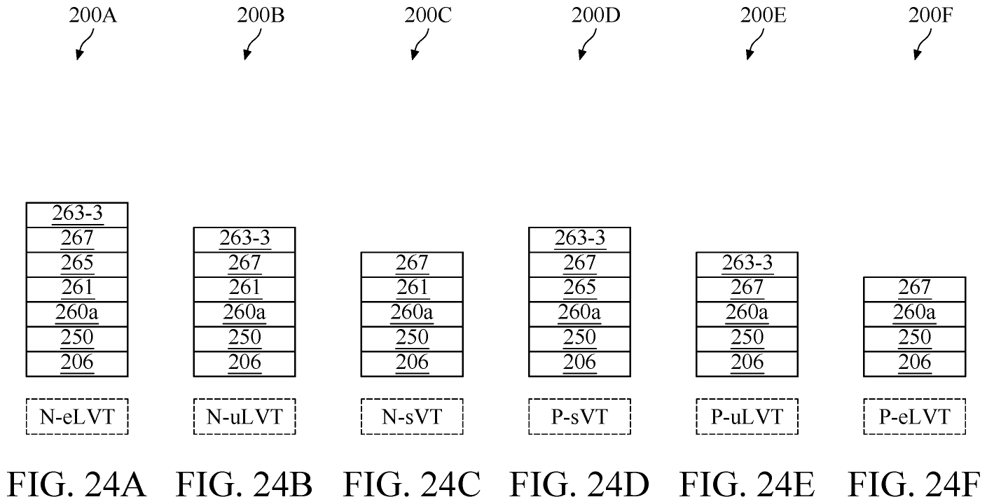

At block 2112, a second N-dipole layer 267 is globally formed on the gate structures 200A-200F, and a patterned resist layer 263-3 is formed on the second N-dipole layer 267 of the gate structures 200A, 200B, 200D, and 200E, as shown in FIGS. 24A-24F. The second N-dipole layer 267 is formed on the first N-dipole layer 265 of the gate structures 200A and 200D, on the turning layers 261 of the gate structures 200B and 200C, and on the first HK dielectric 260a of the gate structures 200E and 200F. The second N-dipole layer 267 may be selected from the material used for the first N-dipole layer 265. In some embodiments, the second N-dipole layer 267 may include the same material as the first N-dipole layer 265. In some embodiments, the second N-dipole layer 267 may include a material that is chemically different than the first N-dipole layer 265. The patterned resist layer 263-3 may be formed in a similar fashion to those discussed above with respect to the patterned resist layer 263-1.

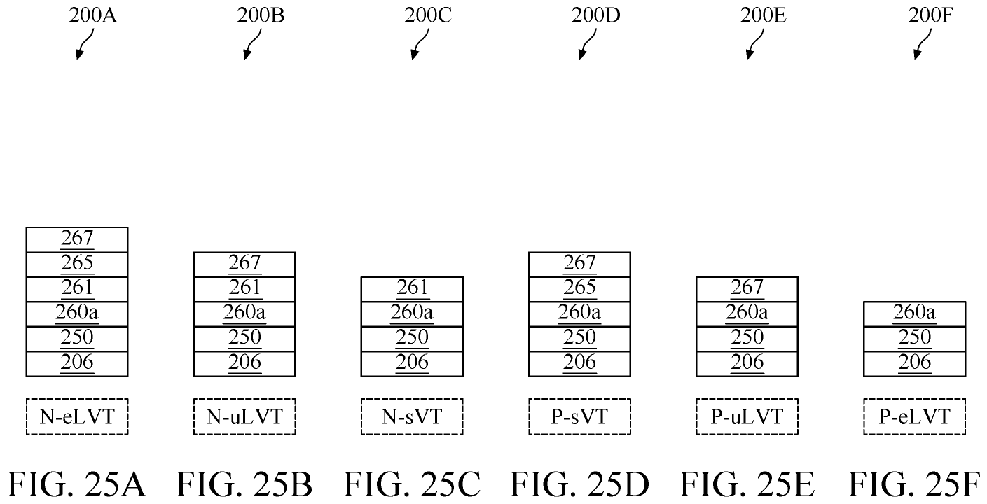

At block 2114, the second N-dipole layers 267 on the gate structures 200C and 200F are removed, and then the patterned resist layers 263-3 are removed, as shown in FIGS. 25A-25F. The second N-dipole layers 267 may be removed, using the patterned resist layer 263-3 as a mask, by any suitable etch process, such as those discussed above for removing the tuning layer 261. The patterned resist layer 263-3 may be removed using any suitable process.

At block 2116, the gate structures 200A-200F are subjected to a thermal treatment 268. The thermal treatment causes the dipole elements in the tuning layer 261, the first N-dipole layer 265, and the second N-dipole layer 267 to penetrate into (or react with) the first HK dielectric 260a to form a modified first HK dielectric 260a-1. The dipole elements may increase the polarity of the first HK dielectric 260a, and thus can be used to adjust the threshold voltage Vth of the gate structures 200A-200F. In some embodiments, the modified first HK dielectric 260a-1 is the first HK dielectric 260a doped with the dipole elements and/or mixed with materials from the tuning layer 261, the first N-dipole layer 265, and the second N-dipole layer 267. The thermal treatment 268 may be performed in-situ or ex-situ and can be any type of anneal, such as rapid thermal anneal, a spike anneal, a soak anneal, a laser anneal, etc. The thermal treatment 268 may be performed for about 1 second to about 3 minutes, and at a temperature range of about 500 degrees Celsius to about 850 degrees Celsius. The thermal treatment 268 may be performed in an atmosphere of gas, such as an oxygen-containing gas, a hydrogen-containing gas, an argon-containing gas, a helium-containing gas, or any combinations thereof. Exemplary gas may include, but is not limited to, N₂, NH₃, O₂, N₂O, Ar, He, H₂, etc.

The annealing temperature causes the dipole elements (e.g., La) to diffuse or drive into a portion of the first HK dielectric 260a. The thermal treatment 268 may be performed such that the dipole elements are eventually distributed in the first HK dielectric 260a, turning it into the modified first HK dielectric 260a-1. Alternatively, the dipole elements may be gradually distributed along the thickness of the modified first HK dielectric 260a-1. In such cases, the dipole elements at and/or near an interface of the modified first HK dielectric 260a-1 and the tuning layer 261 on, for example, the gate structures 200A-200C, may have a first dopant concentration, and the dipole elements at and/or near an interface of the modified first HK dielectric 260a-1 and the IL 250 may have a second dopant concentration that is lower than the first dopant concentration.

In some embodiments, a portion of the tuning layer 261, the first N-dipole layer 265, or the second N-dipole layer 267 may react with the first HK dielectric 260a, resulting in the modified first HK dielectric 260a-1 that is a compound, a composition, or a mixture of the first HK dielectric 260a and the tuning layer 261, the first N-dipole layer 265, and the second N-dipole layer 267.

In some embodiments, a portion of the IL 250, such as the region 269 of the IL 250 near or at an interface between the modified first HK dielectric 260a-1 and the IL 250, may also be modified. Likewise, the modified IL 250 can be a layer doped with the dipole elements and/or mixed with materials from the tuning layer 261, the first N-dipole layer 265, and the second N-dipole layer 267, depending on the thermal treatment used and the duration of the thermal treatment 268. In such cases, the dipole elements at and/or near an interface between the modified first HK dielectric 260a-1 and the IL 250 on, for example, the gate structures 200A-200C, may have a third dopant concentration, and the dipole elements at and/or near an interface of the IL 250 and the channel region (i.e., first semiconductor layer 106) may have a fourth dopant concentration that is lower than the third dopant concentration.

It is contemplated that while the thermal treatment 268 is discussed herein to perform after all the tuning layer 261, the first N-dipole layer 265, and the second N-dipole layer 267 are formed, the thermal treatment 268 may be performed separately after the tuning layer 261 is formed and/or after the first N-dipole layer 265 is formed.

As such, the multiple patterning processes discussed above result in different numbers of first and second N-dipole layers as well as tuning layers 261 overlying the first HK dielectric 260a on the gate structures 200A-200F. Since different numbers of the first N-dipole layer 265, the second N-dipole layer 267, and the tuning layer 261 are arranged on the gate structures 200A-200F, the modified first HK dielectric 260a-1 on certain gate structures will have a dopant concentration (of the dipole elements) different than the modified first HK dielectric 260a-1 on other gate structures for different threshold voltage requirements needed for the N-type devices and P-type devices. For example, the modified first HK dielectrics 260a-1 on the gate structures 200A and 200D may have a first dopant concentration, and the modified first HK dielectrics 260a-1 on the gate structures 200B and 200E may have a second dopant concentration, and the modified first HK dielectrics 260a-1 on the gate structures 200C and 200F may have a third dopant concentration. In some embodiments, the first dopant concentration is greater than the second dopant concentration due to the presence of the first N-dipole layer 265, the second N-dipole layer 267, and the tuning layer 261, and the dopant concentration of the modified first HK dielectric 260a-1 on the gate structure 200A is greater than the dopant concentration of the modified first HK dielectric 260a-1 on the gate structure 200D due to the inclusion of the tuning layer 261. In some embodiments, the second dopant concentration is greater than the third dopant concentration due to the presence of second N-dipole layer 267 and the tuning layer 261. The dopant concentration of the modified first HK dielectric 260a-1 on the gate structure 200B is greater than the dopant concentration of the modified first HK dielectric 260a-1 on the gate structure 200E due to the inclusion of the tuning layer 261. Lastly, for the gate structures 200C and 200F, the first N-dipole layer 265 and the second N-dipole layer 267 are not present. Therefore, the modified first HK dielectric 260a-1 may have the lowest dopant concentration for the gate structure 200C due to the presence of the tuning layer 261, and the modified first HK dielectric 260a-1 on the gate structure 200F may have fewest, or substantially free of, dipole elements.

While not shown, integrated circuit devices such as the semiconductor device structure 100 may include various transistors having different threshold voltages based on their function in the IC device. For example, input/output (IO) transistors may have the highest threshold voltages due to the high current handling required for the IO transistors. Core logic transistors may have the lowest threshold voltages to achieve higher switching speeds at lower operating power. A third threshold voltage between that of the IO transistors and that of the core logic transistors may be employed for other functional transistors, such as static random access memory (SRAM) transistors. In some embodiments, the semiconductor device structure 100 may include two or more NFETs and/or PFETs of two or more different threshold voltages.

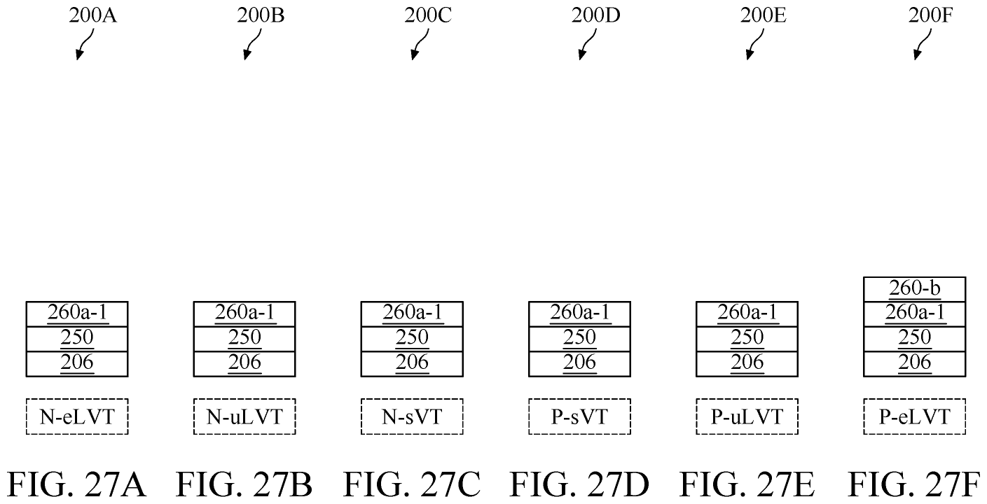

At block 2118, the first N-dipole layer 265, the second N-dipole layer 267, and the tuning layer 261 are removed from the gate structures 200A-200F, as shown in FIG. 27A-27F. The first N-dipole layer 265, the second N-dipole layer 267, and the tuning layer 261 may be removed using any suitable removal process, such as a wet etch process or those discussed above for removing the tuning layer 261. The removal process may be time controlled or be performed until the modified first HK dielectrics 260a-1 are exposed.

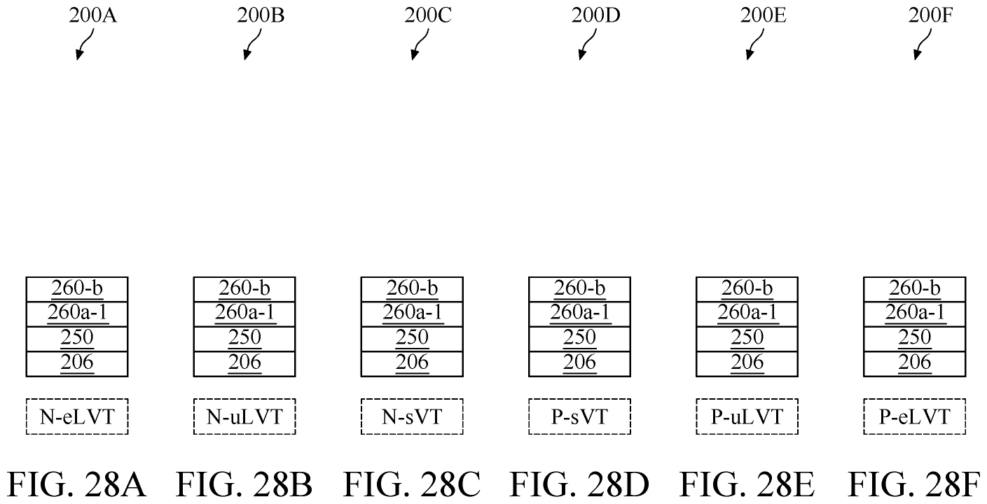

At block 2120, a second HK dielectric 260b is globally formed on the modified first HK dielectric 260a-1 of the gate structures 200A-200F, as shown in FIGS. 28A-28F. The second HK dielectric 260b may include the same material as the second HK dielectric 160b, and may be deposited by an ALD process as those discussed above with respect to FIG. 14. The ALD process may be performed using between about 20 and about 40 deposition cycles, at a temperature range between about 200 degrees Celsius and about 300 degrees Celsius. In some embodiments, the ALD process uses HfCl₄ and/or H₂O as precursors. Such an ALD process may form the second HK dielectric 260b to have a thickness in a range of about 5 Angstroms to about 15 Angstroms. In some embodiments, the modified first HK dielectric 260a-1 and the second HK dielectric 260b may have a combined thickness in a range of about 10 Angstroms to about 30 Angstroms.

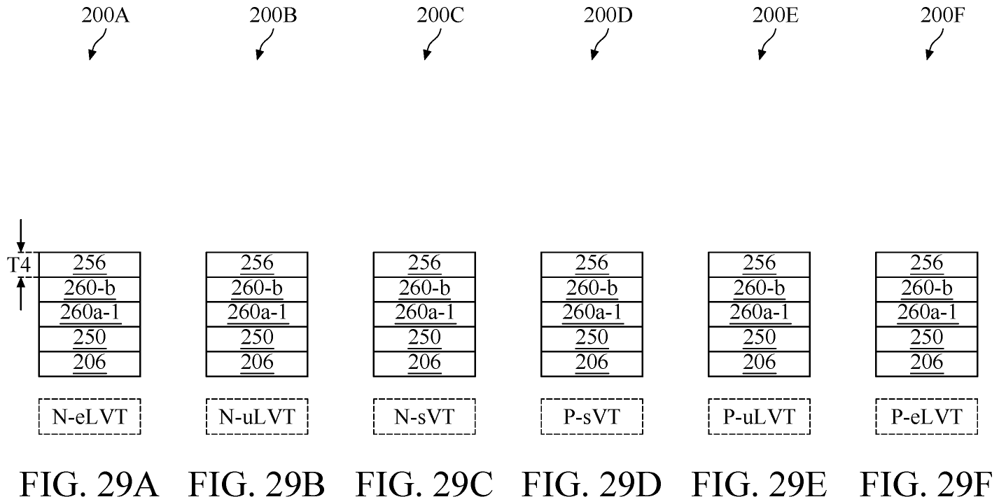

At block 2122, an insertion layer 256 is globally formed over the second HK dielectric 260b of the gate structures 200A-200F, as shown in FIGS. 29A-29F. The insertion layer 256 may include the same material as the insertion layer 156, and may be conformally formed on the second HK dielectric layer 260b in a similar fashion to those discussed above with respect to FIG. 15. Like the insertion layer 156, the insertion layer 256 serves as an oxygen barrier that blocks oxygen migration from the gate dielectrics (e.g., modified first HK dielectric layer 260a and second HK dielectric layer 260b) to a subsequently formed metal gate (e.g., metal layer 258, FIG. 30A). The insertion layer 256 can reduce generation of oxygen vacancies in the modified first HK dielectric layer 260a and second HK dielectric layer 260b, prevent the metal gate from increasing the resistivity thereof due to oxidation, and promote stress relaxation of the channel regions. Since generation of oxygen vacancies is suppressed by the insertion layer 256, the number of thermal treatments for repairing oxygen vacancies can be reduced, thereby avoiding thickening of the IL 250 (due to IL re-growth) and diffusion of dopants in the source/drain features. The insertion layer 256 may have a thickness T4 in a range of about 2 Angstroms to about 10 Angstroms.

At block 2124, a metal layer 258 and a metal fill layer 259 are globally formed over the insertion layer 256 of the gate structures 200A-200F, as shown in FIGS. 30A-30F. The metal layer 258 forms the electrode portion of the gate structures 200A-200F. The metal layer 258 may be a low resistance metal with a P-type band edge effective work function value (P-metal). That is, the metal layer 258 is a P-type band edge work function metal having an effective work function value higher than the mid-gap work function value (about 4.5 eV), which is in the middle of the valance band and the conduction band of silicon. The work function value higher than the mid-gap work function is referred to as a P-work function, and the respective metal having the P-work function is referred to as a P-metal. In some embodiments, the metal layer 258 is a pure metal having an effective work function value (eWF) ranging from about 4.7 eV to about 5.7 eV. In some embodiments, the metal layer 258 has an effective work function value in a range of about 4.9 eV to about 5.2 eV. The metal layer 258 may include tungsten (W), chromium (Cr), ruthenium (Ru), molybdenum (Mo), osmium (Os), titanium (Ti), rhenium (Re), rhodium (Rh), iridium (Ir), platinum (Pt), nickel (Ni), or any other low resistance pure metal with a P-type band edge effective work function value. The metal layer 258 may be deposited using any suitable conformal deposition technique such as ALD, such that the metal layer 258 contains minimal voids or other defects that may increase gate resistance.

After the metal layer 258 is deposited, the metal fill layer 259 are formed over the metal layer 258. The metal fill layer 259 may include an electrically conductive material such as W, cobalt (Co), Ru, Ir, Mo, copper (Cu), aluminum (Al), Ti, tantalum (Ta), or the like, or combination thereof. The metal fill layer 259 may be formed of a material different from the metal layer 258. The metal fill layer 259 may be deposited using CVD, PVD, plating, and/or other suitable deposition techniques.

While not shown, a capping layer, a barrier layer, N-metal work function layer, P-metal work function layer, and/or a glue layer may be disposed between the insertion layer 256 and the metal fill layer 259. The capping layer and the barrier layer may be metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be formed of a material different from the capping layer. The N-metal work function layer may be formed from a metallic material such as W, Cu, AlCu, TiAlC, TiAlN, Ti, TiN, Ta, TaN, Co, Ni, Ag, Al, TaAl, TaAlC, TaC. TaCN, TaSiN, Mn, Zr, other suitable N-type work function materials, or combinations thereof. The P-metal work function layer may be formed from a metallic material such as W, Al, Cu, TiN, Ti, TiAlN, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The glue layer may be formed of a metal nitride, such as TiN, TaN, MON, WN, or other suitable material, using an ALD process.

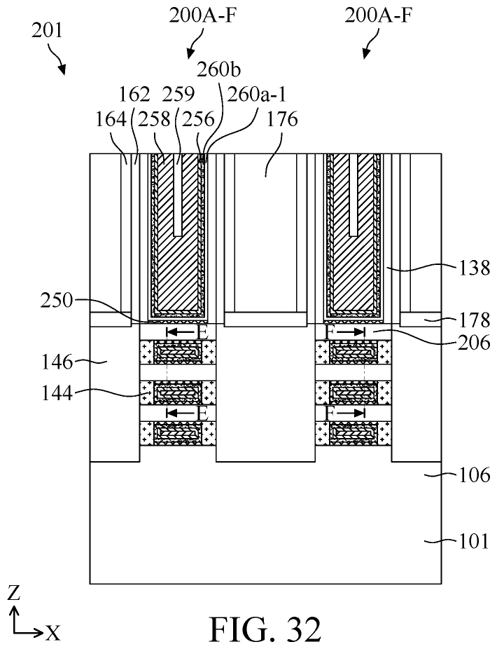

After the gate structures 200A-200F are formed, S/D contacts 176 may be formed through the ILD layer 164 and the CESL 162 to expose the epitaxial S/D feature 146. A silicide layer 178 is disposed on the epitaxial S/D features 146 to conductively couple the epitaxial S/D features 146 to the S/D contacts 176. FIG. 32 is a cross-sectional view of a semiconductor device structure 201 showing an intermediate stage of fabrication, such as the stage after the replacement gates (e.g., gate structures 200A-200F) and the S/D contacts 176 have been formed. The semiconductor device structure 201 is substantially similar to the semiconductor device structure 100 shown in FIG. 17A except for the gate structure 190 is being replaced with the gate structures 200A-200F shown in FIGS. 30A-30F.

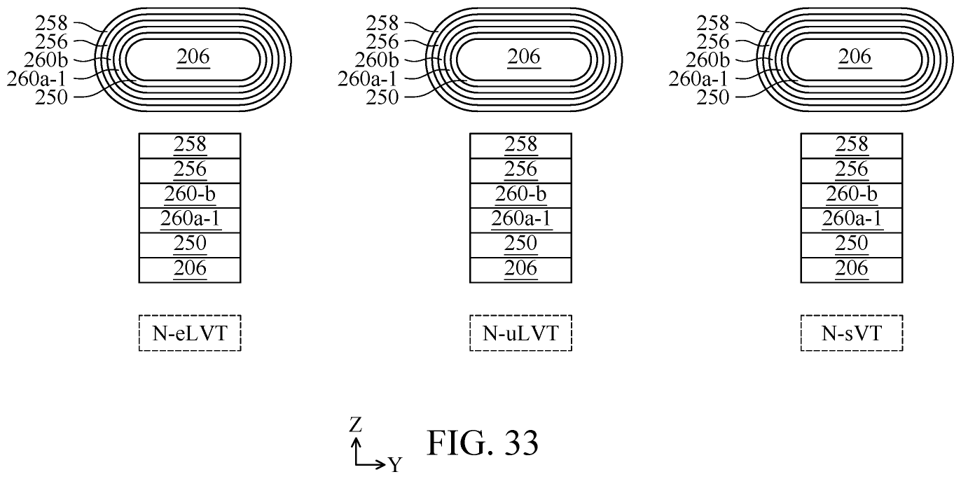

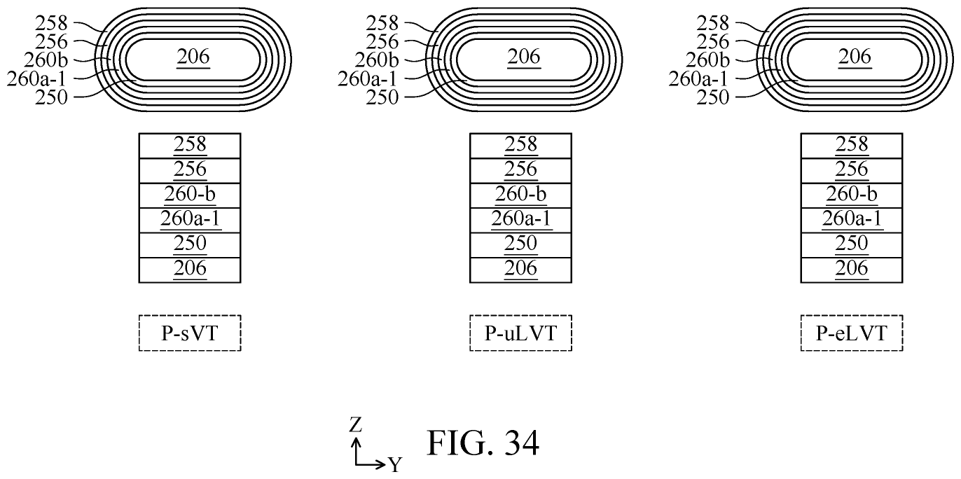

FIG. 33 illustrates a cross-sectional view of a portion of the semiconductor device structure 201 taken along cross-section E-E of FIG. 32, in accordance with some embodiments. FIG. 33 shows an exemplary embodiment of a channel region (i.e., first semiconductor layer 206) working with an N-type extreme low threshold voltage (N-eLVT) gate structure, an N-type ultra low threshold voltage (N-uLVT) gate structure, and an N-type standard threshold voltage (N-sVT) gate structure, respectively. FIG. 34 illustrates a cross-sectional view of a portion of the semiconductor device structure 201 taken along cross-section F-F of FIG. 32, in accordance with some embodiments. FIG. 34 shows an exemplary embodiment of a channel region (i.e., first semiconductor layer 206) working with a P-type standard threshold voltage (P-sVT) gate structure, a P-type ultra low threshold voltage (P-uLVT) gate structure, and a P-type extreme low threshold voltage (P-eLVT) gate structure. Both FIGS. 33 and 34 show the first semiconductor layers 206 being wrapped around by, in an order of, the IL 250, the modified first HK dielectric 260a-1, the second HK dielectric 260b, the insertion layer 256, and the metal layer 258.

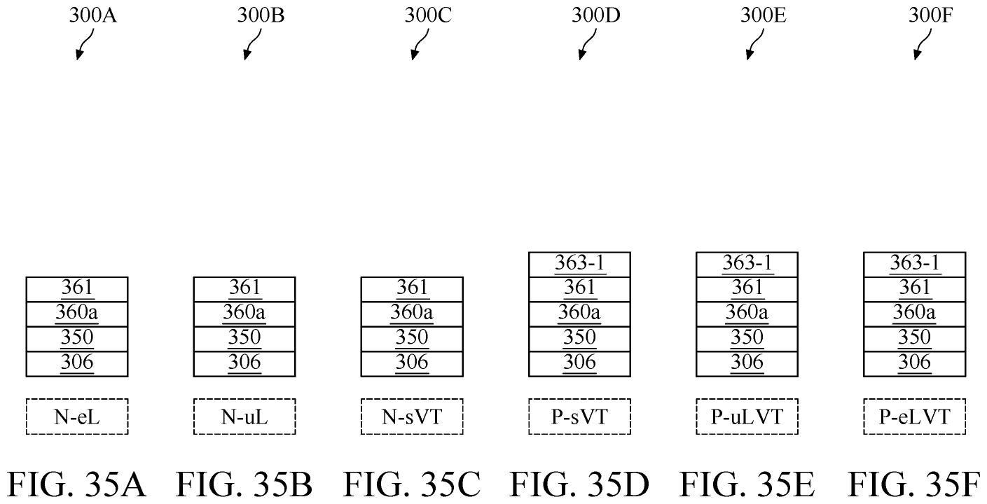

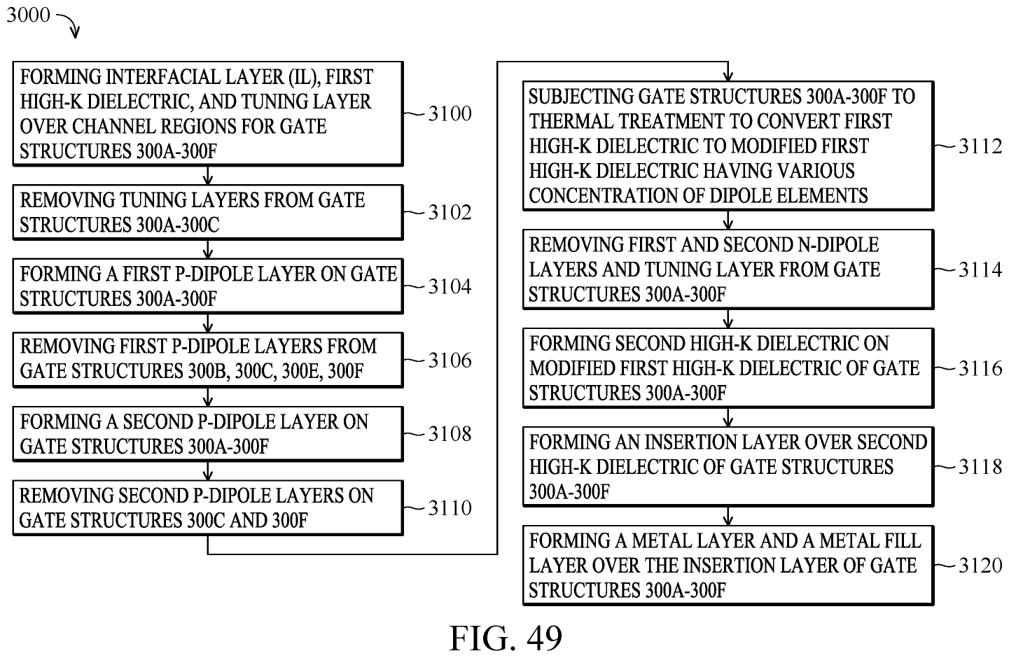

The ultra-thin oxygen barrier (e.g., insertion layer 256) may also be combined with a mature P-dipole process to achieve a single N-edge work-function metal knob. FIGS. 35A through 45F illustrate formation of gate structures 300A-300F for a semiconductor device 301, such as a multiple threshold voltage GAA FET structure, in accordance with various embodiments. FIG. 49 illustrates a flowchart of a process 3000 for forming the gate structures 300A-300F shown in FIGS. 35A-45F, in accordance with various embodiments. FIGS. 35A-45A illustrate formation of a transistor having an N-type extreme low threshold voltage (N-eLVT) gate structure, such as the gate structure 300A. FIGS. 35B-45B illustrate formation of a transistor having an N-type ultra low threshold voltage (N-uLVT) gate structure, such as the gate structure 300B. FIGS. 35C-45C illustrate formation of a transistor having an N-type standard threshold voltage (N-sVT) gate structure, such as the gate structure 300C. FIGS. 35D-45D illustrate formation of a transistor having a P-type standard threshold voltage (P-sVT) gate structure, such as the gate structure 300D. FIGS. 35E-45E illustrate formation of a transistor having a P-type ultra low threshold voltage (P-uLVT) gate structure, such as the gate structure 300E. FIGS. 35F-45F illustrate formation of a transistor having a P-type extreme low threshold voltage (P-eLVT) gate structure, such as the gate structure 300F. Likewise, the gate structures 300A-300F may be applied to FinFETs, GAA FETs, CFETs, forksheet FETs, vertical FETs, etc.

The gate structures 300A-300F may be formed on the same wafer and/or may be parts of the same IC device in some embodiments. As such, at least some of the fabrication processes discussed below may be performed to all the gate structures 300A-300F simultaneously.

At block 3100, the gate structures 300A-300F are shown at an intermediate stage of fabrication, where each gate structure 300A-300F includes a first semiconductor layers 306 (such as the first semiconductor layers 206 shown in FIGS. 20A-20F), an IL 350 (such as the IL 250, FIGS. 20A-20F), a first HK dielectric 360a (such as the first semiconductor layers 206 shown in FIGS. 20A-20F), and a tuning layer 361 (such as the tuning layer 261 shown in FIGS. 20A-20F), as shown in FIGS. 35A-35F. A patterned resist layer 363-1 (such as the patterned resist layer 263-1 shown in FIGS. 20A-20C) is then selectively formed over the gate structures 300D-300F, in a similar fashion to those discussed above with respect to FIGS. 20A-20F. The tuning layer 361 may be a dielectric material containing dipole element(s) suitable for Vth tuning for P-type devices. The tuning layer 361 may be an oxide-based or non-oxide based dielectric material. In some embodiments, the tuning layer 361 is a metal oxide material, in which the metal may include, but is not limited to, zinc (Zn), germanium (Ge), aluminum (Al), titanium (Ti), vanadium (V), or combinations thereof. Exemplary metal oxide for the tuning layer 361 may include ZnOₓ, GeOₓ, AlOₓ, TiOₓ, VOₓ, or the like. The tuning layer 361 may be formed using a conformal deposition process, such as an ALD process. For the gate structures 300D-300F, the tuning layer 361 may increase or compensate for the threshold voltage Vth needed for P-type transistor devices. Similar to the tuning layer 261, the tuning layer 361 may have a thickness in a range between about 3 Angstroms and about 12 Angstroms, for example about 5 Angstroms to about 8 Angstroms.

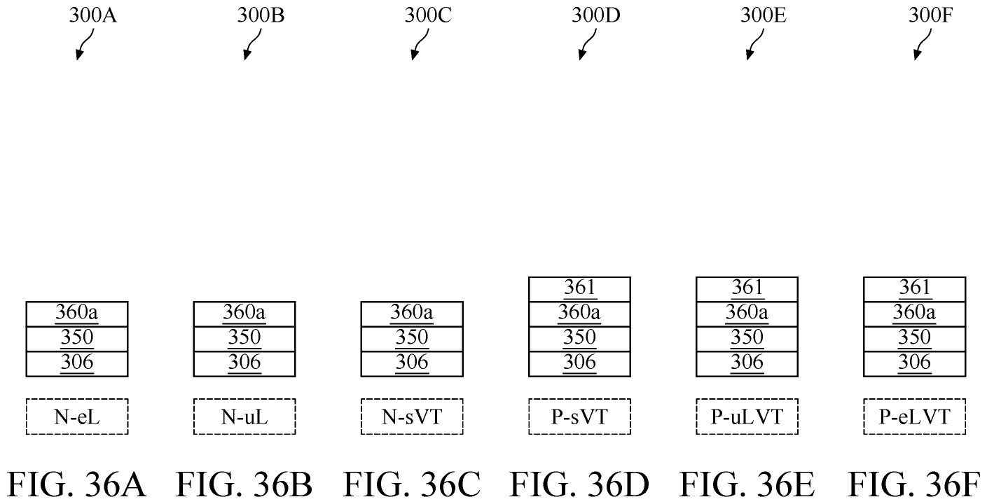

At block 3102, the tuning layers 361 on the gate structures 300A-300C are removed using the patterned resist layer 363-1 as a mask, and then the patterned resist layer 363-1 is removed, as shown in FIGS. 36A-36F. The tuning layers 261 and the patterned resist layer 363-1 may be removed by any suitable removal process, such as those discussed above with respect to FIGS. 21A-21F.

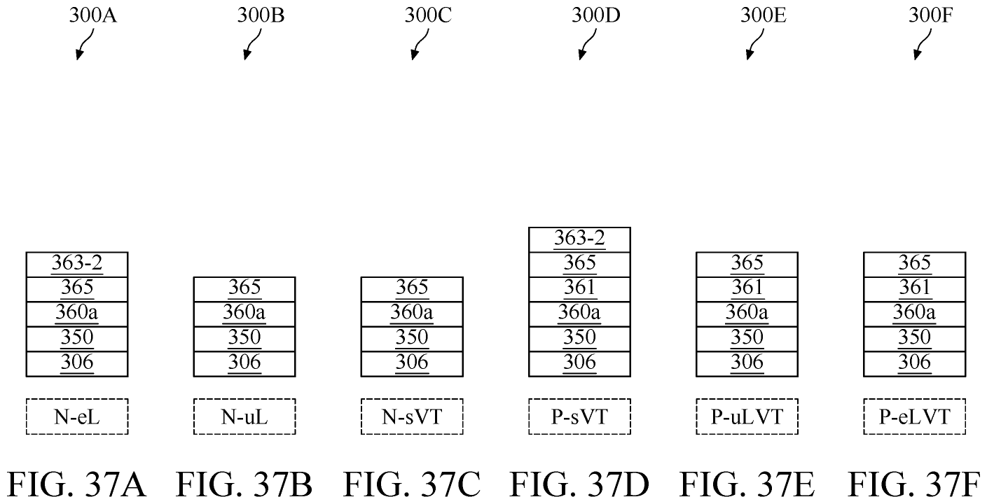

At block 3104, a first P-dipole layer 365 is globally formed on the gate structures 300A-300F, and a patterned resist layer 363-2 is formed over the first P-dipole layer 365 of the gate structures 300A and 300D, as shown in FIGS. 37A-37F. The first P-dipole layer 365 is formed on the tuning layers 361 of the gate structures 300D-300F, and on the first HK dielectric 360a of the gate structures 300A-300C. The first P-dipole layer 365 is a material inherently including a positive polarity. In some embodiments, the first P-dipole layer 365 is a dielectric material containing dipole element(s) suitable for P-type devices. The first P-dipole layer 365 may be selected from the material used for the tuning layer 361. In some embodiments, the first P-dipole layer 365 may include the same or different material than the tuning layer 361. Exemplary material for the first P-dipole layer 365 may include ZnOₓ, GeOₓ, AlOₓ, TiOₓ, VOₓ, or the like. For the gate structures 300D-300F, the first P-dipole layer 365 may increase the threshold voltage Vth needed for P-type transistor devices. For the gate structures 300A-300C corresponding to N-type transistor devices, the first P-dipole layer 365 may decrease the threshold voltage Vth for N-type transistor devices. The first P-dipole layer 365 and the tuning layer 361 may be formed using a conformal deposition process, such as an ALD process. Each of the first P-dipole layers 365 may have a thickness in a range between about 1 Angstroms and about 6 Angstroms, for example about 2 Angstroms to about 3 Angstroms.

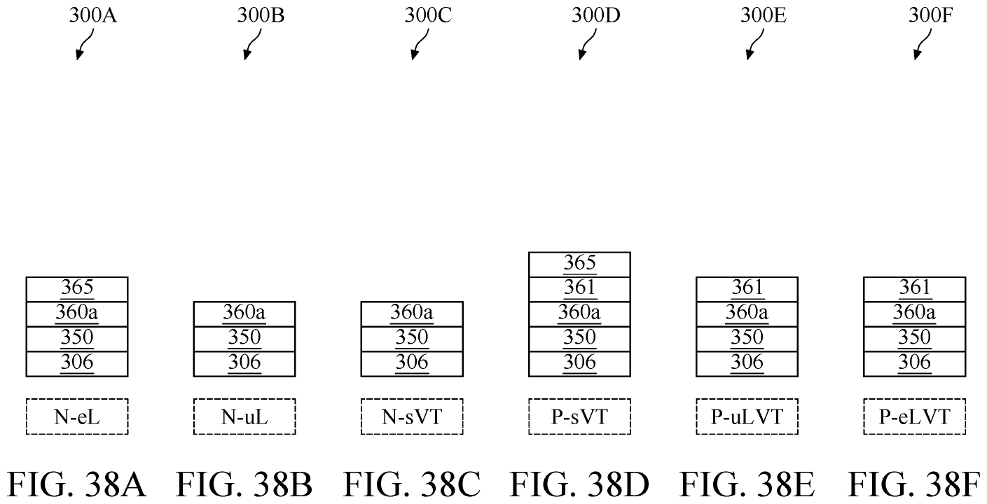

At block 3106, the first P-dipole layers 365 on the gate structures 300B, 300C, 300E, and 300F are removed using the patterned resist layer 363-2 as a mask, and then the patterned resist layer 363-2 is removed, as shown in FIGS. 38A-38F. The first P-dipole layers 365 and the patterned resist layer 363-2 may be removed by any suitable removal process, such as those discussed above with respect to FIGS. 23A-23F.

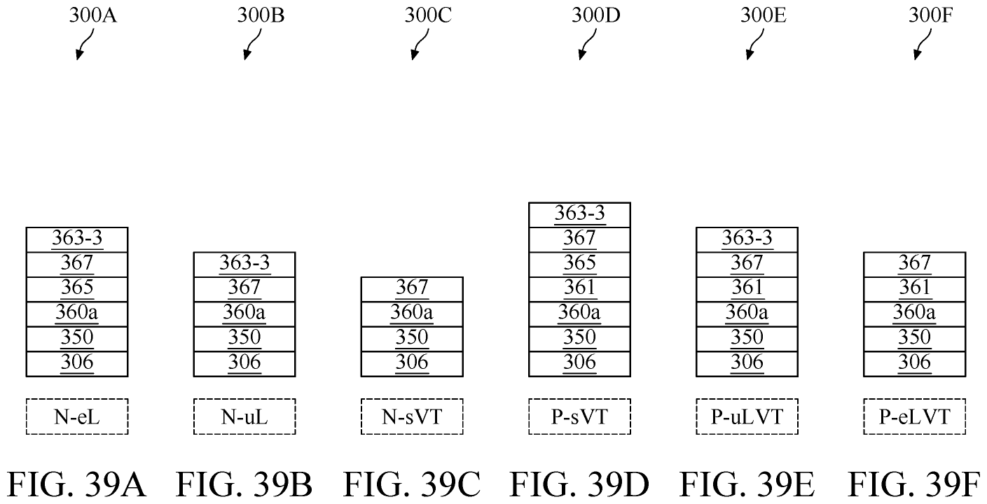

At block 3108, a second P-dipole layer 367 is globally formed on the gate structures 300A-300F, and a patterned resist layer 363-3 is formed on the second P-dipole layer 367 of the gate structures 300A, 300B, 300D, and 300E, as shown in FIGS. 39A-39F. The second P-dipole layer 367 is formed on the first P-dipole layer 365 of the gate structures 300A and 300D, on the turning layers 361 of the gate structures 300E and 300F, and on the first HK dielectric 360a of the gate structures 300B and 300C. The second N-dipole layer 367 may be selected from the material used for the first P-dipole layer 365. The second P-dipole layer 367 may include the same or different material than the first P-dipole layer 365. The patterned resist layer 363-3 may be formed in a similar fashion to those discussed above with respect to the patterned resist layer 363-1.

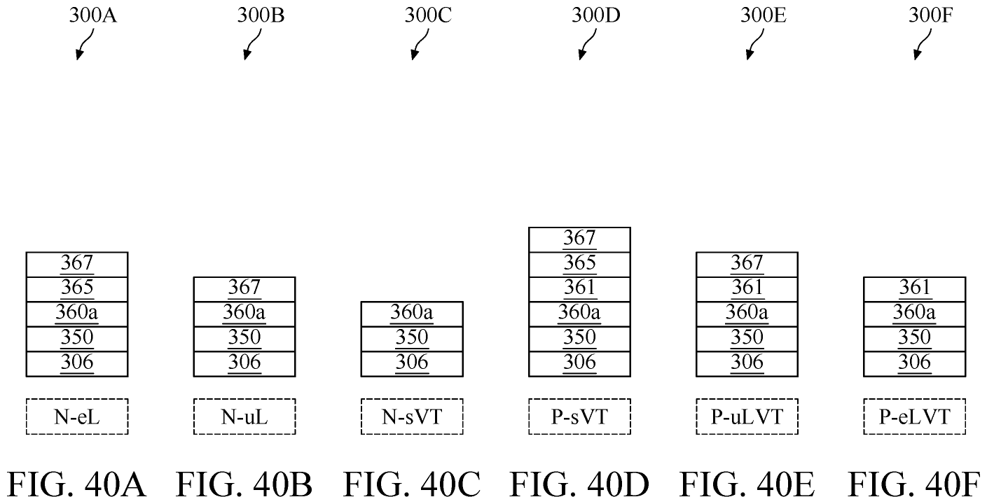

At block 3110, the second P-dipole layers 367 on the gate structures 300C and 300F are removed using the patterned resist layer 363-3 as a mask, and then the patterned resist layers 363-3 are removed, as shown in FIGS. 40A-40F. The second P-dipole layers 367 and the patterned resist layer 363-3 may be removed using any suitable process, such as those discussed above with respect to FIGS. 25A-25F.

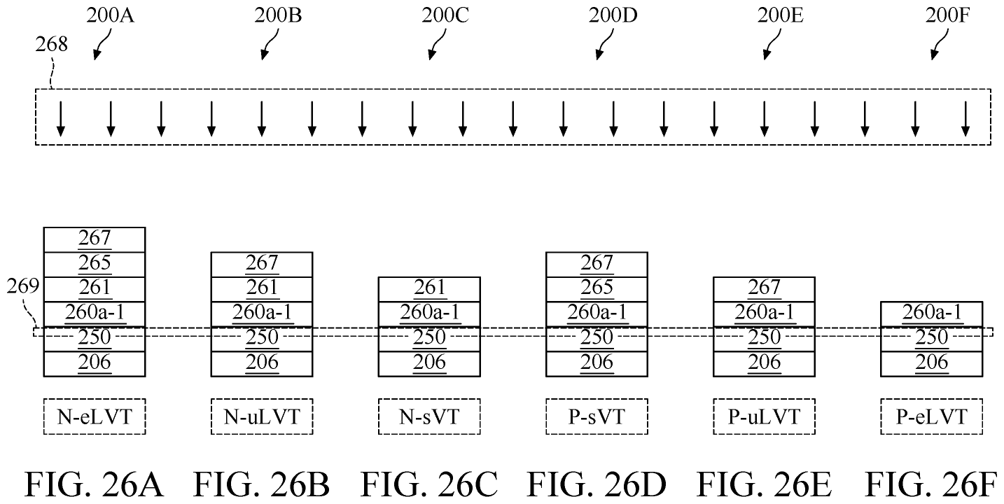

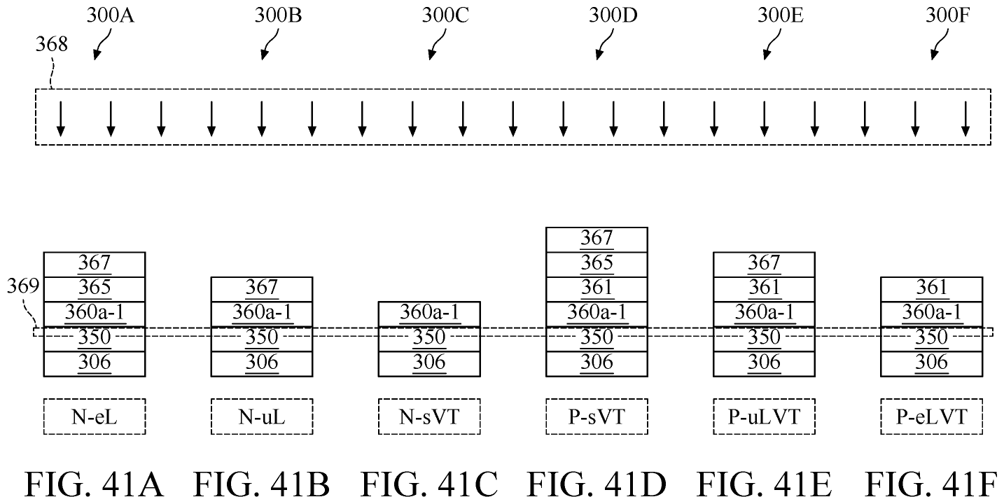

At block 3112, the gate structures 300A-300F are subjected to a thermal treatment 368 (such as thermal treatment 268 shown in FIGS. 26A-26F), as shown in FIGS. 41A-41F. Likewise, the thermal treatment 368 causes the dipole elements in the tuning layer 361, the first P-dipole layer 365, and the second P-dipole layer 367 to penetrate into (or react with) the first HK dielectric 360a to form a modified first HK dielectric 360a-1. The dipole elements may increase the polarity of the first HK dielectric 360a, and thus can be used to adjust the threshold voltage Vth of the gate structures 300A-300F. In some embodiments, the modified first HK dielectric 360a-1 is the first HK dielectric 360a doped with the dipole elements and/or mixed with materials from the tuning layer 361, the first P-dipole layer 365, and the second P-dipole layer 367.

The annealing temperature causes the dipole elements (e.g., Ge) to diffuse or drive into a portion of the first HK dielectric 360a. The thermal treatment 368 may be performed such that the dipole elements are eventually distributed in the first HK dielectric 360a, turning it into the modified first HK dielectric 360a-1. Alternatively, the dipole elements may be gradually distributed along the thickness of the modified first HK dielectric 360a-1. In such cases, the dipole elements at and/or near an interface of the modified first HK dielectric 360a-1 and the tuning layer 361 on, for example, the gate structures 300D-300F, may have a first dopant concentration, and the dipole elements at and/or near an interface of the modified first HK dielectric 360a-1 and the IL 350 may have a second dopant concentration that is lower than the first dopant concentration.

In some embodiments, a portion of the tuning layer 361, the first P-dipole layer 365, or the second P-dipole layer 367 may react with the first HK dielectric 360a, resulting in the modified first HK dielectric 360a-1 that is a compound, a composition, or a mixture of the first HK dielectric 360a and the tuning layer 361, the first P-dipole layer 365, and the second P-dipole layer 367.

In some embodiments, a portion of the IL 350, such as the region 369 of the IL 350 near or at an interface between the modified first HK dielectric 360a-1 and the IL 350, may also be modified. Likewise, the modified IL 350 can be a layer doped with the dipole elements and/or mixed with materials from the tuning layer 361, the first P-dipole layer 365, and the second P-dipole layer 367. In such cases, the dipole elements at and/or near an interface between the modified first HK dielectric 360a-1 and the IL 350 on, for example, the gate structures 300D-300F, may have a third dopant concentration, and the dipole elements at and/or near an interface of the IL 350 and the channel region (i.e., first semiconductor layer 306) may have a fourth dopant concentration that is lower than the third dopant concentration.

It is contemplated that while the thermal treatment 368 is discussed herein to perform after all the tuning layer 361, the first P-dipole layer 365, and the second P-dipole layer 367 are formed, the thermal treatment 368 may be performed separately after the tuning layer 361 is formed and/or after the first P-dipole layer 365 is formed.

As such, the multiple patterning processes discussed above result in different numbers of first and second P-dipole layers as well as tuning layers 361 overlying the first HK dielectric 360a on the gate structures 300A-300F. Since different numbers of the first P-dipole layer 365, the second P-dipole layer 367, and the tuning layer 361 are arranged on the gate structures 300A-300F, the modified first HK dielectric 360a-1 on certain gate structures will have a dopant concentration (of the dipole elements) different than the modified first HK dielectric 360a-1 on other gate structures for different threshold voltage requirements needed for the N-type devices and P-type devices. For example, the modified first HK dielectrics 360a-1 on the gate structures 300A and 300D may have a first dopant concentration, and the modified first HK dielectrics 360a-1 on the gate structures 300B and 300E may have a second dopant concentration, and the modified first HK dielectrics 360a-1 on the gate structures 300C and 300F may have a third dopant concentration. In some embodiments, the first dopant concentration is greater than the second dopant concentration due to the presence of the first P-dipole layer 365, the second P-dipole layer 367, and the tuning layer 361, and the dopant concentration of the modified first HK dielectric 360a-1 on the gate structure 300D is greater than the dopant concentration of the modified first HK dielectric 360a-1 on the gate structure 300A due to the inclusion of the tuning layer 361. In some embodiments, the second dopant concentration is greater than the third dopant concentration due to the presence of second P-dipole layer 367 and the tuning layer 261. The dopant concentration of the modified first HK dielectric 360a-1 on the gate structure 300E is greater than the dopant concentration of the modified first HK dielectric 360a-1 on the gate structure 300B due to the inclusion of the tuning layer 361. Lastly, for the gate structures 300C and 300F, the first P-dipole layer 365 and the second P-dipole layer 367 are not present. Therefore, the modified first HK dielectric 360a-1 may have the lowest dopant concentration for the gate structure 300F due to the presence of the tuning layer 361, and the modified first HK dielectric 360a-1 on the gate structure 300C may have fewest, or substantially free of, dipole elements.

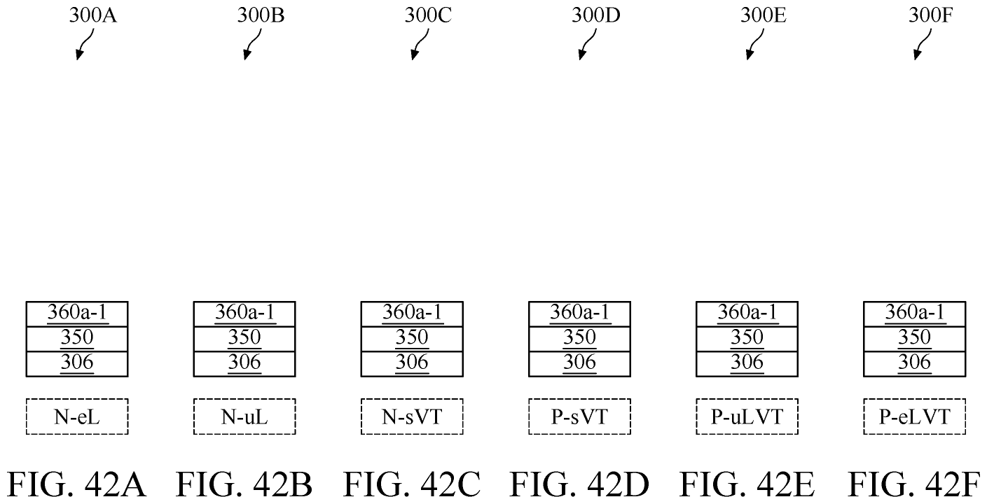

At block 3114, the first P-dipole layer 365, the second P-dipole layer 367, and the tuning layer 361 are removed from the gate structures 300A-300F, as shown in FIGS. 42A-42F. The first P-dipole layer 365, the second P-dipole layer 367, and the tuning layer 361 may be removed using any suitable removal process, such as a wet etch process or those discussed above for removing the tuning layer 361. The removal process may be time controlled or be performed until the modified first HK dielectrics 360a-1 are exposed.

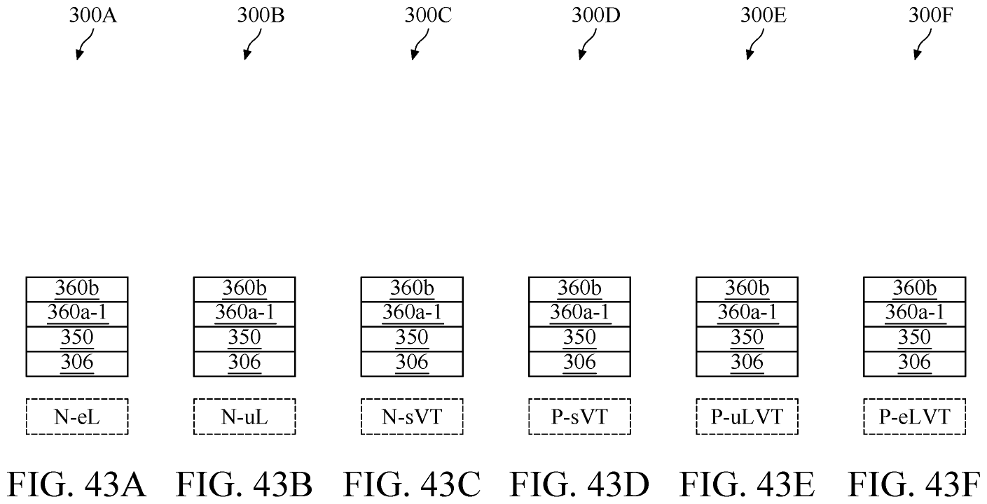

At block 3116, a second HK dielectric 360b is globally formed on the modified first HK dielectric 360a-1 of the gate structures 300A-300F, as shown in FIGS. 43A-43F. The second HK dielectric 360b may include the same material as the second HK dielectric 260b, and may be deposited by an ALD process as those discussed above with respect to FIGS. 28A-28F. The second HK dielectric 360b may have a thickness in a range of about 5 Angstroms to about 15 Angstroms. In some embodiments, the modified first HK dielectric 360a-1 and the second HK dielectric 360b may have a combined thickness in a range of about 10 Angstroms to about 30 Angstroms.

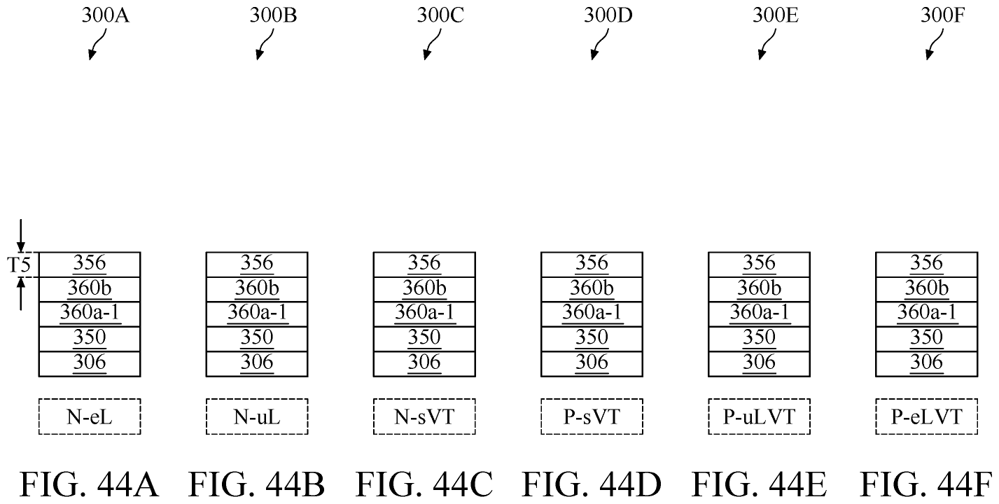

At block 3118, an insertion layer 356 is globally formed over the second HK dielectric 360b of the gate structures 300A-300F, as shown in FIGS. 44A-44F. The insertion layer 356 may include the same material as the insertion layer 256, and may be conformally formed on the second HK dielectric layer 360b in a similar fashion to those discussed above with respect to FIG. 15. Like the insertion layer 256, the insertion layer 356 serves as an oxygen barrier that blocks oxygen migration from the gate dielectrics (e.g., modified first HK dielectric layer 360a and second HK dielectric layer 360b) to a subsequently formed metal gate (e.g., metal layer 358, FIGS. 45A-45F). The insertion layer 356 can reduce generation of oxygen vacancies in the modified first HK dielectric layer 360a and second HK dielectric layer 360b and protect the metal gate from further oxidation. Since generation of oxygen vacancies is suppressed by the insertion layer 356, the number of thermal treatments for repairing oxygen vacancies can be reduced, thereby avoiding thickening of the IL 350 (due to IL re-growth) and diffusion of dopants in the source/drain features. Since noble metal for oxygen barrier has a work function close to that of P-edge work function metal, the thickness of the insertion layer 356 is thinner than the that of the insertion layer 256. In some embodiments, the insertion layer 356 may have a thickness T5 in a range of about 1 Angstroms to about 8 Angstroms. In some embodiments, the thickness T5 is less than the thickness T4 (FIGS. 29A-29F).

At block 3120, a metal layer 358 and a metal fill layer 359 are globally formed over the insertion layer 356 of the gate structures 300A-300F, as shown in FIGS. 45A-45F. The metal layer 358 forms the electrode portion of the gate structures 300A-300F. The metal layer 358 may be a low resistance metal with an N-type band edge effective work function value (N-metal). That is, the metal layer 358 is an N-type band edge work function metal having an effective work function value lower than the mid-gap work function value (about 4.5 eV), which is in the middle of the valance band and the conduction band of silicon. The work function value lower than the mid-gap work function is referred to as a N-work function, and the respective metal having the N-work function is referred to as a N-metal. In some embodiments, the metal layer 358 is a pure metal having an effective work function value (eWF) ranging from about 3.8 eV to about 4.2 eV. The metal layer 358 may include tantalum (Ta), zirconium (Zr), cadmium (Cd), indium (In), Al, or any other low resistance pure metal with an N-type band edge effective work function value. The metal layer 358 may be deposited using any suitable conformal deposition technique such as ALD.

After the metal layer 358 is deposited, the metal fill layer 359 are formed over the metal layer 358. The metal fill layer 359 may include the same material as the metal fill layer 259, and may be deposited using any suitable deposition technique. The metal fill layer 359 may be formed of a material different from the metal layer 358.

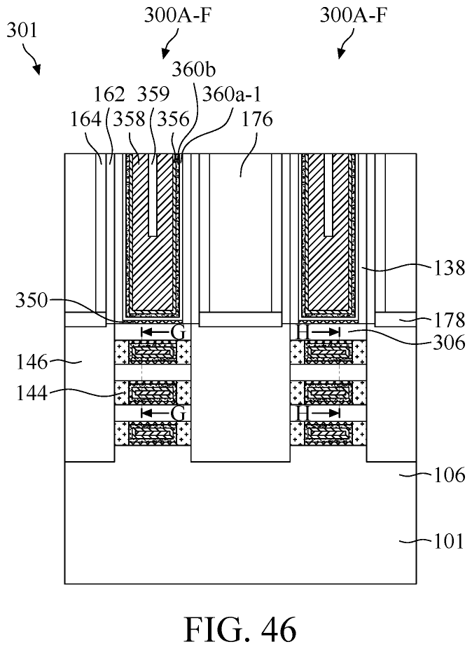

While not shown, a capping layer, a barrier layer, N-metal work function layer, P-metal work function layer, and/or a glue layer, such as those discussed above with respect to FIG. 32, may be disposed between the insertion layer 356 and the metal fill layer 359. After the gate structures 300A-300F are formed, S/D contacts 176 may be formed through the ILD layer 164 and the CESL 162 to expose the epitaxial S/D feature 146. A silicide layer 178 is disposed on the epitaxial S/D features 146 to conductively couple the epitaxial S/D features 146 to the S/D contacts 176. FIG. 46 is a cross-sectional view of a semiconductor device structure 301 showing an intermediate stage of fabrication, such as the stage after the replacement gates (e.g., gate structures 300A-300F) and the S/D contacts 176 have been formed. The semiconductor device structure 301 is substantially similar to the semiconductor device structure 100 shown in FIG. 17A except for the gate structure 190 is being replaced with the gate structures 300A-300F shown in FIGS. 45A-45F.

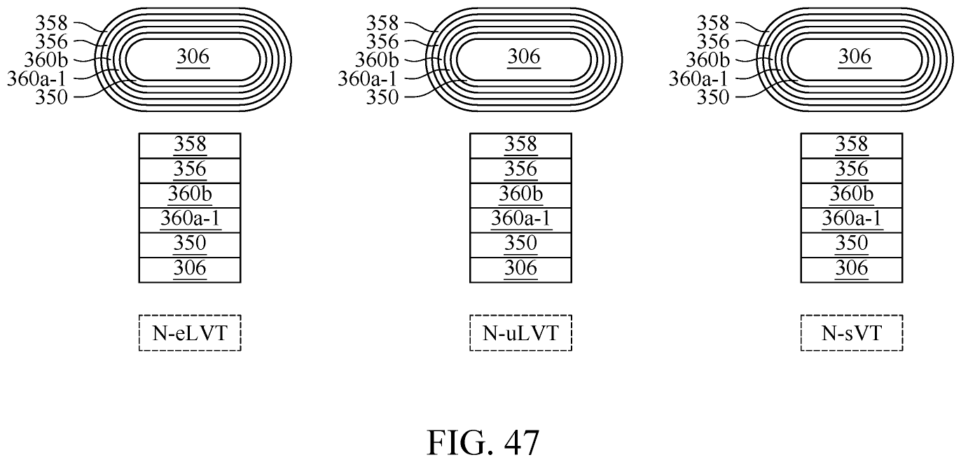

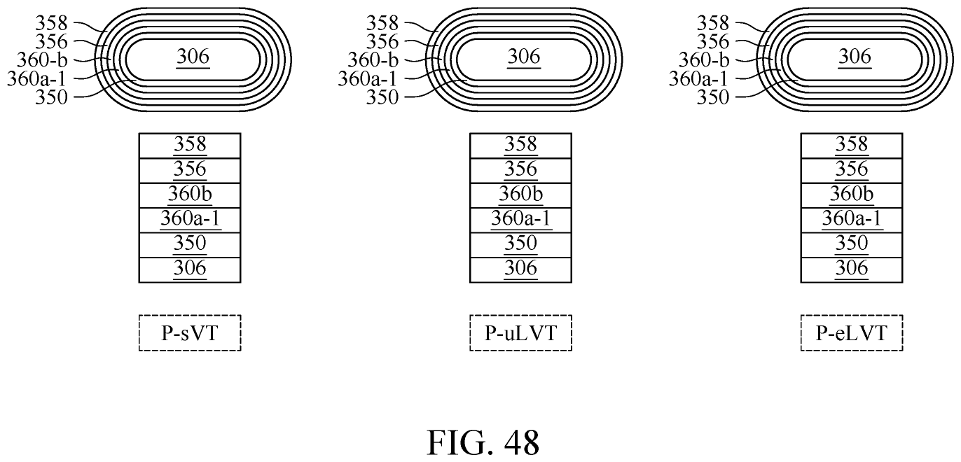

FIG. 47 illustrates a cross-sectional view of a portion of the semiconductor device structure 301 taken along cross-section G-G of FIG. 46, in accordance with some embodiments. FIG. 47 shows an exemplary embodiment of a channel region (i.e., first semiconductor layer 306) working with an N-type extreme low threshold voltage (N-cLVT) gate structure, an N-type ultra low threshold voltage (N-uLVT) gate structure, and an N-type standard threshold voltage (N-sVT) gate structure, respectively. FIG. 48 illustrates a cross-sectional view of a portion of the semiconductor device structure 301 taken along cross-section H-H of FIG. 46, in accordance with some embodiments. FIG. 48 shows an exemplary embodiment of a channel region (i.e., first semiconductor layer 306) working with a P-type standard threshold voltage (P-sVT) gate structure, a P-type ultra low threshold voltage (P-uLVT) gate structure, and a P-type extreme low threshold voltage (P-eLVT) gate structure. Both FIGS. 47 and 48 show the first semiconductor layers 306 being wrapped around by, in an order of, the IL 350, the modified first HK dielectric 360a-1, the second HK dielectric 360b, the insertion layer 356, and the metal layer 358.

Various embodiments or examples described herein offer multiple advantages over the state-of-art technology. According to embodiments of the present disclosure, an ultra-thin oxygen barrier (i.e., insertion layer 156, 256, 356) is disposed between gate dielectrics and metal gate to prevent oxygen migration from the gate dielectric to the metal gate. The oxygen barrier keeps oxygen in the gate dielectrics (thus less generation of oxygen vacancies in the gate dielectrics) and protect the metal gate from further oxidation, thereby avoiding high RG (metal gate resistivity) caused by metal gate oxidization during the downstream process (e.g., packaging and/or bonding processes). The oxygen barrier may be combined with a N-dipole or P-dipole process for simplification of process difficulty, increase of throughput, and reduction of cost for advanced technology nodes. Since generation of oxygen vacancies is suppressed by the oxygen barrier, the number of thermal treatments for repairing oxygen vacancies can be reduced, thereby avoiding IL re-growth and diffusion of dopants in source/drain features.

An embodiment is a semiconductor device structure. The structure includes a semiconductor channel layer over a substrate, a gate dielectric layer disposed over the semiconductor channel layer. The gate dielectric layer includes a first high-K (HK) dielectric layer having a first dopant concentration of dipole elements, and a second HK dielectric layer having a second dopant concentration of dipole elements different than the first dopant concentration. The structure also includes a gate electrode layer deposited over the gate dielectric layer, and an insertion layer disposed between the gate dielectric layer and the gate electrode layer, wherein the insertion layer is formed of a noble metal.

Another embodiment is a semiconductor device structure. The structure includes a first gate structure surrounding a first semiconductor layer. The first gate structure includes a first dielectric layer having a first dopant concentration of dipole elements, a first metal layer over the first dielectric layer, and a first insertion layer disposed between the first dielectric layer and the first metal layer, wherein the first insertion layer is formed of a noble metal. The structure also includes a second gate structure surrounding a second semiconductor layer, wherein the second gate structure includes a second dielectric layer having a second dopant concentration of dipole elements different than the first dopant concentration of dipole elements. The structure also includes a second metal layer over the second dielectric layer, and a second insertion layer disposed between the second dielectric layer and the second metal layer, wherein the second insertion layer is formed of the noble metal.

A further embodiment is a method for forming a semiconductor device structure. The method includes forming an interfacial layer (IL) over a plurality of semiconductor channel layers at first and second device regions, forming a first high-K (HK) dielectric over the IL, forming a tuning layer over the first HK dielectric, wherein the tuning layer comprises dipole elements suitable for tuning threshold voltage for devices having a first conductivity type. The method also includes removing the tuning layer over the selected semiconductor channel layers at the second device region, forming a first dipole layer over each semiconductor channel layer at the first and second device regions, wherein the first dipole layer comprises dipole elements suitable for devices having the first conductivity type. The method also includes removing the first dipole layer over the selected semiconductor channel layers at the first and second device regions, forming a second dipole layer over each semiconductor channel layer at the first and second device regions, wherein the second dipole layer comprises dipole elements suitable for devices having a second conductivity type. The method also includes removing the second dipole layer over the selected semiconductor channel layers at the first and second device regions, driving in dipole elements from the tuning layer, the first dipole layer, and the second dipole layer to the first HK dielectric, removing the tuning layer, the first dipole layer, and the second dipole layer over each semiconductor channel layer at the first and second device regions, forming an insertion layer over the first HK dielectric, wherein the insertion layer is formed of a noble metal. The method further includes forming a metal layer on the insertion layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a semiconductor channel layer over a substrate;
a gate dielectric layer disposed over the semiconductor channel layer, comprising:
a first high-K (HK) dielectric layer having a first dopant concentration of dipole elements; and
a second HK dielectric layer having a second dopant concentration of dipole elements different than the first dopant concentration;
a gate electrode layer deposited over the gate dielectric layer; and
an insertion layer disposed between the gate dielectric layer and the gate electrode layer, wherein the insertion layer comprises a noble metal.

2. The semiconductor device structure of claim 1, further comprising:
an interfacial layer (IL) disposed between the semiconductor channel layer and the first HK dielectric layer, wherein the IL has a third dopant concentration of dipole elements that is less than the first dopant concentration.

3. The semiconductor device structure of claim 1, wherein the noble metal comprises gold (Au), platinum (Pt), iridium (Ir), palladium (Pd), osmium (Os), silver (Ag), rhodium (Rh), ruthenium (Ru), or the like.

4. The semiconductor device structure of claim 1, wherein the noble metal is an oxide of noble metal.

5. The semiconductor device structure of claim 4, wherein the insertion layer is a multi-layer structure comprising a first layer containing the noble metal and a second layer containing a noble metal oxide.

6. The semiconductor device structure of claim 1, wherein the insertion layer is disposed between and in contact with the second HK dielectric layer and the gate electrode layer.

7. The semiconductor device structure of claim 1, wherein the gate electrode layer is a P-type band edge work function metal having an effective work function value ranging from about 4.7 eV to about 5.7 eV.

8. The semiconductor device structure of claim 1, wherein the gate electrode layer is an N-type band edge work function metal having an effective work function value ranging from about 3.8 eV to about 4.2 eV.

9. A semiconductor device structure, comprising:
a first gate structure surrounding a first semiconductor layer, comprising:
a first dielectric layer having a first dopant concentration of dipole elements;
a first metal layer over the first dielectric layer; and
a first insertion layer disposed between the first dielectric layer and the first metal layer, wherein the first insertion layer is formed of a noble metal; and
a second gate structure surrounding a second semiconductor layer, the second gate structure comprising:
a second dielectric layer having a second dopant concentration of dipole elements different than the first dopant concentration of dipole elements;
a second metal layer over the second dielectric layer; and
a second insertion layer disposed between the second dielectric layer and the second metal layer, wherein the second insertion layer is formed of the noble metal.

10. The semiconductor device structure of claim 9, further comprising:
a third gate structure surrounding a third semiconductor layer, the third gate structure comprising:
a third dielectric layer that is substantially free of dipole elements;
a third metal layer over the third dielectric layer; and
a third insertion layer disposed between the third dielectric layer and the third metal layer, the third insertion layer is formed of the noble metal.

11. The semiconductor device structure of claim 10, wherein the first gate structure is an N-type extreme low threshold voltage (N-eLVT) gate structure, and the second gate structure is an N-type ultra low threshold voltage (N-uLVT) gate structure, and the third gate structure is a P-type extreme low threshold voltage (P-eLVT) gate structure.

12. The semiconductor device structure of claim 10, further comprising:
a fourth gate structure surrounding a fourth semiconductor layer, the fourth gate structure comprising:
a fourth dielectric layer having a third dopant concentration of dipole elements that is different than the first and second dopant concentration of dipole elements;
a fourth metal layer over the fourth dielectric layer; and
a fourth insertion layer disposed between the fourth dielectric layer and the fourth metal layer, the fourth insertion layer is formed of the noble metal.

13. The semiconductor device structure of claim 12, wherein the fourth gate structure is an N-type standard threshold voltage (N-sVT) gate structure.

14. The semiconductor device structure of claim 12, wherein the first, second, third, and fourth metal layers are a P-type band edge work function metal having an effective work function value ranging from about 4.7 eV to about 5.7 eV.

15. The semiconductor device structure of claim 9, wherein the noble metal comprises gold (Au), platinum (Pt), iridium (Ir), palladium (Pd), osmium (Os), silver (Ag), rhodium (Rh), ruthenium (Ru), or the like.

16. The semiconductor device structure of claim 9, wherein the noble metal is an oxide of noble metal that is electrically conductive.

17. A method for forming a semiconductor device structure, comprising:
forming an interfacial layer (IL) over a plurality of semiconductor channel layers at first and second device regions;
forming a first high-K (HK) dielectric over the IL;
forming a tuning layer over the first HK dielectric, the tuning layer comprising dipole elements suitable for tuning threshold voltage for devices having a first conductivity type;
removing the tuning layer over the selected semiconductor channel layers at the second device region;
forming a first dipole layer over each semiconductor channel layer at the first and second device regions, the first dipole layer comprising dipole elements suitable for devices having the first conductivity type;
removing the first dipole layer over the selected semiconductor channel layers at the first and second device regions;
forming a second dipole layer over each semiconductor channel layer at the first and second device regions, the second dipole layer comprising dipole elements suitable for devices having a second conductivity type;
removing the second dipole layer over the selected semiconductor channel layers at the first and second device regions;
driving in dipole elements from the tuning layer, the first dipole layer, and the second dipole layer to the first HK dielectric;
removing the tuning layer, the first dipole layer, and the second dipole layer over each semiconductor channel layer at the first and second device regions;
forming an insertion layer over the first HK dielectric, wherein the insertion layer is formed of a noble metal; and
forming a metal layer on the insertion layer.

18. The method of claim 17, further comprising:
prior to forming the insertion layer, forming a second HK dielectric on the first HK dielectric.

19. The method of claim 17, wherein the first HK dielectric over a first semiconductor channel layer at the first device region has a first dopant concentration of dipole elements, and the first dielectric over a second semiconductor channel layer at the first device region has a second concentration of dipole elements that is different than the first dopant concentration of dipole elements.

20. The method of claim 19, wherein the first HK dielectric over a first semiconductor channel layer at the second device region has a third dopant concentration of dipole elements, and the third concentration of dipole elements is different than the first and second dopant concentration of dipole elements.
